(19) United States
(12) Patent Application Publication
(10) Pub. No.: US 2013/0247937 A1
(43) Pub. Date: Sep. 26, 2013

(54) SUBSTRATE PROCESSING APPARATUS AND ITS MAINTENANCE METHOD, SUBSTRATE TRANSFER METHOD AND PROGRAM

(71) Applicant: HITACHI KOKUSAI ELECTRIC INC., Tokyo (JP)

(72) Inventors: Ichiro NUNOMURA, Toyama-shi (JP); Satoru TAKAHATA, Toyama-shi (JP)

(21) Appl. No.: 13/785,125

(22) Filed: Mar. 5, 2013

(30) Foreign Application Priority Data
Mar. 5, 2012 (JP) 2012-048304
Feb. 12, 2013 (JP) 2013-024308

(51) Int. Cl. H01L 21/67

(52) U.S. Cl. CPC H01L 21/67069
USPC 134/18; 156/345.51; 156/345.24

(57) ABSTRACT

There is provided a substrate processing apparatus, including at least: a substrate holder that holds a substrate; a processing furnace including a reaction tube in which the substrate holder is loaded, and is configured to apply a specific processing to the substrate held by the substrate holder in a state that the substrate holder is loaded in the reaction tube; an operation part configured to select a maintenance recipe for the reaction tube used for substrate processing, and a maintenance recipe for both of the reaction tube and the substrate holder loaded in the reaction tube; and a control part configured to execute the maintenance recipe selected by the operation part, when a maintenance timing of the reaction tube and/or the substrate holder arrives.

### BACKGROUND

1. Technical Field

The present invention relates to a substrate processing apparatus that processes a substrate and a maintenance method of the same, a substrate transfer method and a program.

2. Description of Related Art

The substrate processing apparatus for substrate processing includes a batch type apparatus having a vertical reaction tube and a substrate holder for holding substrates in multiple stages, and configured to supply a processing gas into the reaction tube and apply processing to the substrate held by the substrate holder, with the substrate holder loaded in the reaction tube. In such a vertical batch type substrate processing apparatus, removal of a piled film thickness is performed simultaneously to both of the reaction tube and the substrate holder by executing a maintenance recipe for cleaning.

Incidentally, in recent years, a vertical substrate processing apparatus is developed, in which for example two substrate holders are prepared to one reaction tube, and the substrate is transferred to other substrate holder to be held thereby, while the substrate held by a certain substrate holder is processed in the reaction tube, to thereby improve a throughput (for example, see patent document 1).
Patent document 1: U.S. Pat. No. 4,851,670

However, in a conventional substrate processing apparatus, cleaning is executed simultaneously to both of the reaction tube and the substrate holder. Therefore, for example even when two substrate holders are prepared, transfer of the substrate of an incoming batch to the substrate holder is inhibited at a timing of performing maintenance to the reaction tube in executing a continuous batch processing, and processing of the incoming batch cannot be executed immediately after end of the maintenance because there is no substrate holder for the incoming batch to which the substrate has been transferred, thus involving a fault that the throughput is poor as a result.

Therefore, an object of the present invention is to provide a substrate processing apparatus configured to allow the substrate to be transferred to the substrate holder not subjected to maintenance, when a piled film thickness adhered to the reaction tube or the substrate holder exceeds a threshold value as a result of loading the substrate holder into the reaction tube for processing the substrate, and maintenance needs to be performed thereto.

According to a first aspect of the present invention, there is provided a substrate processing apparatus, including:

an operation part configured to select a maintenance recipe for a reaction tube used for substrate processing, and a maintenance recipe for both of the reaction tube and a substrate holder loaded in the reaction tube; and

a control part configured to execute the maintenance recipe selected by the operation part, after end of the substrate processing when a maintenance timing of the reaction tube and/or the substrate holder arrives during execution of the substrate processing using the reaction tube.

According to the present invention, processing can be performed to the incoming batch immediately after the maintenance is performed by allowing the substrate of the incoming batch to be transferred, even when a maintenance timing arrives to be performed to the reaction tube or the substrate holder during execution of the continuous batch processing, thus improving a throughput.

### BRIEF DESCRIPTION OF THE DRAWINGS

FIG. 1 is an overall perspective view of a substrate processing apparatus according to a first embodiment of the present invention.

FIG. 2 is a planar cross-sectional view of the substrate processing apparatus according to the first embodiment of the present invention.

FIG. 3 is a vertical cross-sectional view of the substrate processing apparatus according to the first embodiment of the present invention.

FIG. 4 is a perspective view of a boat transfer part of the substrate processing apparatus according to the first embodiment of the present invention.

FIG. 5 is a vertical cross-sectional view of a processing furnace of the substrate processing apparatus according to the first embodiment of the present invention.

FIG. 6 is a block diagram showing a controller part of the substrate processing apparatus according to the first embodiment of the present invention.

FIG. 7A to FIG. 7I are an explanatory views showing a substrate transfer method performed in a substrate processing apparatus 1 according to the first embodiment of the present invention.

FIG. 8 is a sequence flow chart showing an execution procedure of a maintenance recipe monitoring program executed in the substrate processing apparatus 1 according to a third embodiment of the present invention.

FIG. 9 is a sequence flow chart showing the execution procedure of the maintenance recipe monitoring program executed in the substrate processing apparatus 1 according to a fourth embodiment of the present invention.

FIG. 10 is a sequence flow chart showing the execution procedure of the maintenance recipe monitoring program executed in the substrate processing apparatus 1 according to a modified example of the fourth embodiment of the present invention.

FIG. 11 is a sequence flow chart showing the execution procedure of the maintenance recipe monitoring program executed in the substrate processing apparatus 1 according to a fifth embodiment of the present invention.

FIG. 12 is a block diagram showing a controller part 200 provided in the substrate processing apparatus 1 according to other embodiment of the present invention.

### DETAILED DESCRIPTION OF THE INVENTION

A first embodiment of the present invention is described hereafter, with reference to the drawings.

### (1) Structure of the Substrate Processing Apparatus

The substrate processing apparatus according to this embodiment performs processing to a substrate by executing a substrate processing process based on a recipe in which a processing procedure and processing conditions are defined, and is configured as a vertical batch type substrate processing apparatus that performs simultaneous processing to a plurality of substrates.

A semiconductor wafer substrate (simply called a “wafer” hereafter) with a semiconductor integrated circuit device (semiconductor device) built therein for example, can be given as a substrate to be processed. Further, as a typical example of processing performed by the substrate processing apparatus, film formation processing such as processing of forming a thin film on a surface of the wafer, can be given.

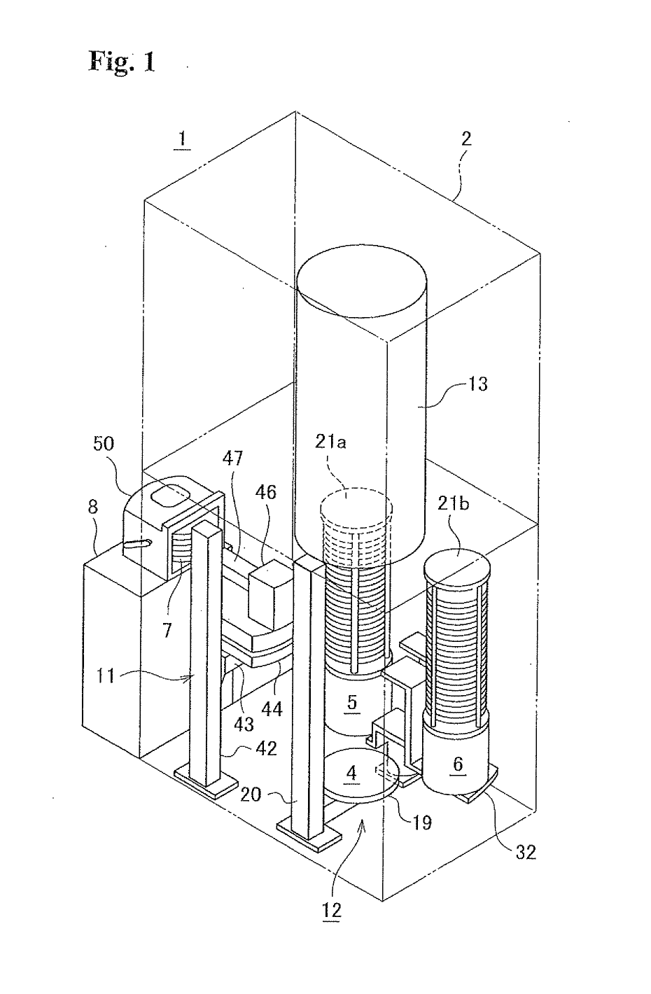

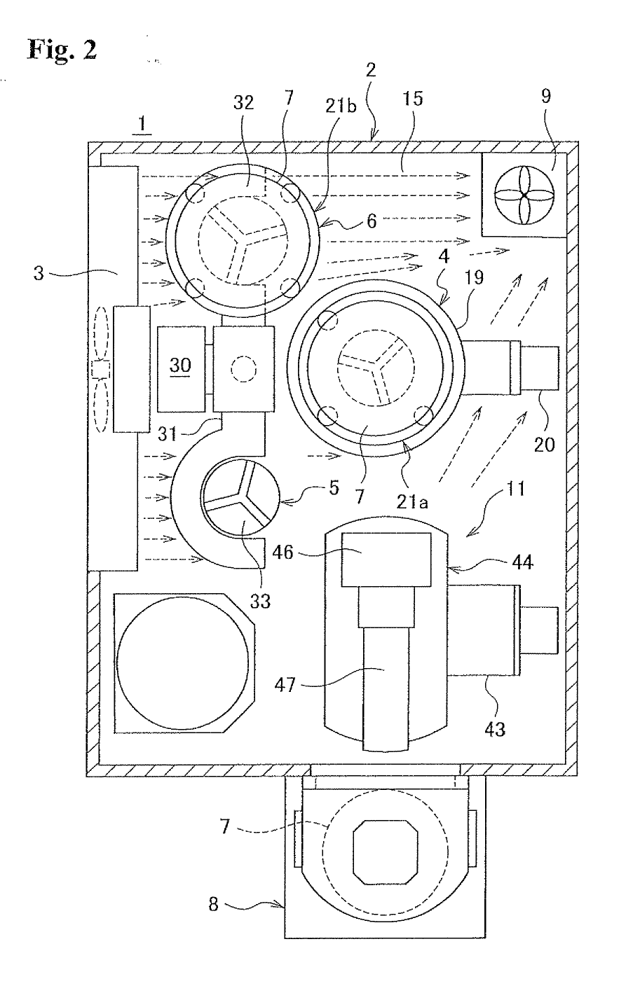

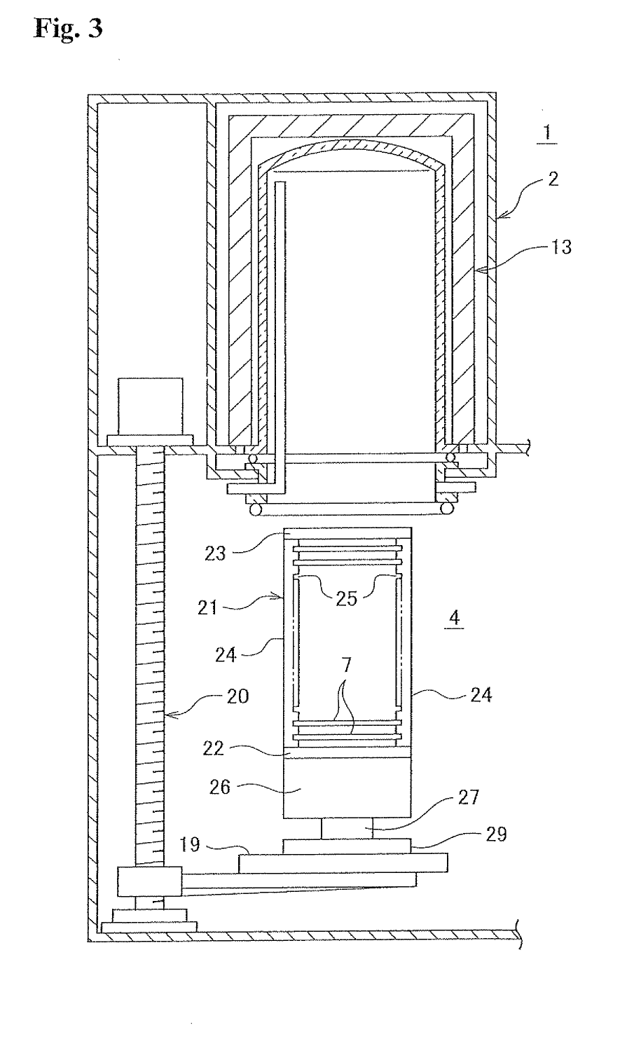

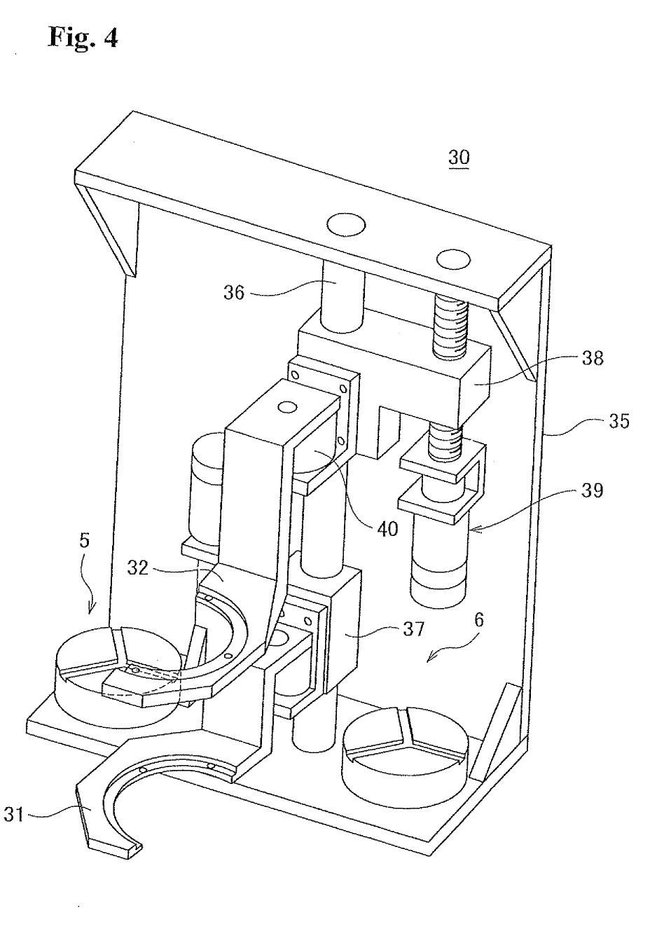

A structure of the substrate processing apparatus according to this embodiment is described hereafter, with reference to FIG. 1 to FIG. 4. FIG. 1 is an overall perspective view of a substrate processing apparatus 1 according to a first embodiment of the present invention. FIG. 2 is a planar cross-sectional view of the substrate processing apparatus 1 according to the first embodiment of the present invention. FIG. 3 is a vertical cross-sectional view of the substrate processing apparatus 1 according to the first embodiment of the present invention. FIG. 4 is a perspective view of a boat transfer part 12 of the substrate processing apparatus 1 according to the first embodiment of the present invention.

### (An Overall Outline Structure of an Apparatus)

As shown in FIG. 1, the substrate processing apparatus 1 according to this embodiment includes a casing 2 configured as a pressure-resistance vessel. A supplying/receiving stage 8 for supplying and receiving a pod 50 being a substrate storage vessel is provided in front of a front face of the casing 2.

The pod 50 is a sealed transfer vessel transferred in a state of storing specific numbers (for example, 25) of wafers 7 being processing objects, and has an openable lid. Specifically, for example FOUP (front opening unified pod) is used as the pod 50. When the FOUP is used, the wafers 7 are transferred in a sealed state, and therefore cleanness of the wafers 7 can be kept even if particles, etc., exist in a circumferential atmosphere. Accordingly, there is no necessity for setting the cleanness to be high in a clean room in which the substrate processing apparatus 1 is set, and a cost required for the clean room can be reduced. Note that the pod 50 is transferred onto the supplying and receiving stage 8 by an external transfer device (not shown) such as OHT (Overhead Hoist Transport), etc., for example, used in a manufacturing step of the semiconductor device.

The supplying/receiving stage 8 is provided for supplying and receiving the pod 50 between the supplying/receiving stage 8 and an outside of the substrate processing apparatus 1, and includes a door open/close device (not shown) for opening and closing a lid (not shown) of the pod 50. Further, a wafer charging/discharging port (not shown) is opened on a front face wall of the casing 2 so as to communicate inside and outside of the casing 2, corresponding to the supplying/receiving stage 8.

The inside of the casing 2 is largely divided as follows: a wafer transfer part 11, a boat transfer part 12, and a processing furnace 13. Note that the structure of the processing furnace 13 will be described later.

### (Wafer Transfer Part)

As shown in FIG. 1 or FIG. 2, the wafer transfer part 11 (placement part 11) is disposed to face the supplying/receiving stage 8, with the wafer charging/discharging port interposed between them, so that each wafer 7 is transferred (placed) between the pod 50 on the supplying/receiving stage 8 and a boat (substrate holder) 21 supported by the boat transfer part 12 as will be described later. More specifically, the wafer transfer part 11 includes an elevator 42 having a feed screw mechanism, an elevation base 43 elevated by the elevator 42, a rotation table 44 rotatably provided on the elevation base 43, and a wafer transfer head 46 provided on the rotation table 44 in an advancing/retracting manner. A wafer transfer plate 47 for holding the wafer 7 is provided on the wafer transfer head 46 vertically in specific stages (in five stages in this embodiment). Then, the wafer transfer part 11 is configured to charge and discharge the wafer 7 to/from the boat 21 (wafer charge) by the cooperation of elevation, rotation, and advancement/retreat.

Further, the wafer transfer part 11 is electrically connected to a mechanical control sub-controller 205 in a controller part 200 as will be described later, so that operations such as elevation, rotation, and advancement/retreat, etc., are controlled by an instruction from the mechanical control sub-controller 205.

### (Boat Transfer Part)

As shown in FIG. 1 or FIG. 2, the boat transfer part 12 is disposed in a rear region of the wafer transfer part 11 (backside when viewed from a front side of the casing 2), and includes three stages 4, 5, 6 for supporting the boat (substrate holder) 21, so as to transfer the boat 21 among the stages 4, 5, 6 respectively.

The boat 21 is configured to horizontally hold a plurality of wafers 7 (for example, about 50 to 125 wafers 7), so as to be arranged vertically with centers thereof aligned. More specifically, as shown in FIG. 3, the boat 21 includes a lower end plate 22, and an upper end plate 23 supported by a plurality of struts 24 (three struts in this embodiment) erected on the lower end plate 22. Substrate holding grooves 25 are inscribed on the struts 24 at a specific pitch. The boat 21 holds the wafer 7 in a horizontal posture by inserting the wafer 7 into the substrate holding grooves 25. A heat insulating cap 26 is formed under the lower end plate 22 of the boat 21, and a base 29 is provided in a lower side of the heat insulating cap 26 through a pillar 27. Thus, an arm of the boat transfer mechanism 30 can be fitted into an interval between the base 29 formed by the pillar 27 and the heat insulating cap 26. Note that the boat 21 is made of a heat-insulating material such as quartz (SiO₂) and silicon carbide (SIC), etc.

A transfer position (abbreviated as “TR” hereafter) stage 5 being a position where charge or discharge of the wafer 7 is performed by the wafer transfer part 11 at a side closest to the wafer transfer part 11, an escape position (abbreviated as “ES” hereafter) stage 6 positioned at a place farthest from the wafer transfer part 11, and a boat load position (abbreviated as “BL” hereafter) stage 4 positioned immediately under the processing furnace 13 between them.

Further, the boat transfer part 12 includes a boat elevator 20 provided so as to correspond to the BL stage 4. The boat elevator 20 is configured to load the boat 21 into the processing furnace 13 from the position of the BL stage 4, and unload the boat 21 from the processing furnace 13 to the position of the BL stage 4. More specifically, as shown in FIG. 3, the boat elevator 20 includes a seal cap 19 on which the boat 21 is placed, and is configured to elevate the seal cap 19 by a feed screw mechanism. Note that the seal cap 19 is formed so as to air-tightly close a furnace throat portion of the processing furnace 13, with the boat 21 loaded into the processing furnace.

Further, as shown in FIG. 2, the boat transfer part 12 includes a boat transfer mechanism 30 provided at a position opposed to the boat elevator 20, with the BL stage 4 sandwiched between them. The boat transfer mechanism 30 is configured to transfer the boat 21 among the TR stage 5, BL stage 4 and the ES stage 6. More specifically, as shown in FIG. 4, the boat transfer mechanism 30 includes a U-shaped frame 35 erected along a wall surface of a casing 2. The frame 35 is provided with a vertical guide shaft 36, with the guide shaft 36 further including a lower slider 37 and an upper slider 38 slidably. A feed screw mechanism 39 in which a screw rod is rotated by a motor, is connected to the upper slider 38, so that the upper slider 38 can be elevated by this feed screw mechanism 39. Further, an upper arm 32 bent in a crank shape is provided on the upper slider 38, with a rotation actuator 40 such as a rotation air cylinder and a rotary solenoid, etc., interposed between them, with this upper arm 32 rotatable by at least 180° by the rotation actuator 40. Further, the feed screw mechanism 39 is also connected to the lower slider 37 in a similar structure, and a lower arm 31 is provided in a crank shape, with the rotation actuator 40 interposed between them. Note that the lower arm 31 and the upper arm 32 are formed so as not to interfere with each other when each of them is rotated. Further, the lower arm 31 and the upper arm 32 are formed in an arc shape respectively, so as to be fitted into a gap formed by the pillar 27 of the boat 21.

Note that the boat transfer part 12 is configured as follows: the boat elevator 20 and the boat transfer mechanism 30, etc., are electrically connected to the mechanical control sub-controller 205 in the controller part 200 as will be described later, and an operation of the boat 12 such as elevation and transfer, etc., is controlled by an instruction from the mechanical control sub-controller 205.

### (Others)

As shown in FIG. 2, one directional flow of a clean air 15 that flows from the TR stage 5 and the ES stage 6, to the BL stage 4, is formed by a clean unit 3 disposed on one side face side of the casing 2 and an exhaust fan 9 disposed on a side face side opposed to the clean unit 3.

### (2) Structure of the Processing Furnace

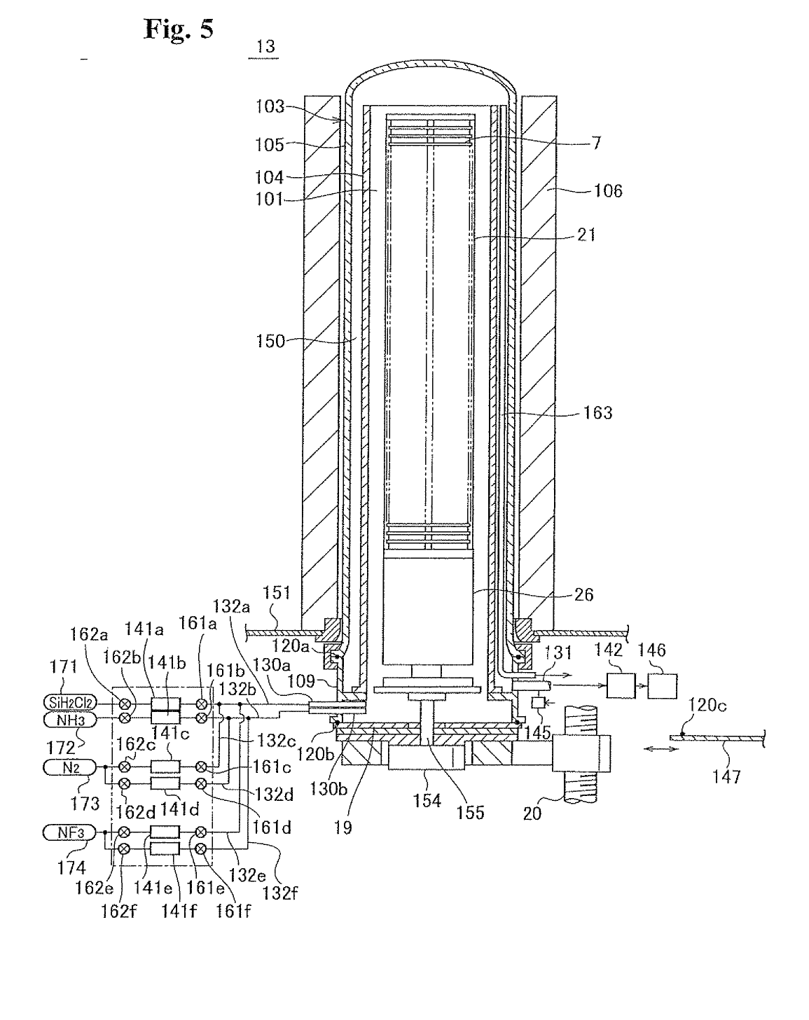

A structure of the processing furnace 13 according to this embodiment will be described next, based on the figures. FIG. 5 is a vertical cross-sectional view of the processing furnace 13 of the substrate processing apparatus 1 according to a first embodiment of the present invention.

The processing furnace 13 is disposed just on the BL stage 4 in the boat transfer part 12 and is configured to apply processing to the wafer 7 held by the boat 21.

### (Processing Chamber)

As shown in FIG. 5, the processing furnace 13 includes a process tube 103 as a reaction tube. The process tube 103 includes an inner tube 104 as an internal reaction tube, and an outer tube 105 as an external reaction tube provided outside of the inner tube 104. The inner tube 104 is made of a heat-resistant material such as quartz (SiO₂) or silicon carbide (SiC), etc. A processing chamber 101 for processing the wafer 7 as a substrate, is formed in a columnar hollow part of the inner tube 104. Therefore, the inner tube 104 is configured to load the boat 21 therein, so that the loaded boat 21 can be housed therein. The outer tube 105 is provided concentrically with the inner tube 104. The outer tube 105 is formed so that an inner diameter is larger than an outer diameter of the inner tube 104, and is formed in a cylindrical shape, with an upper end closed and a lower end opened. The outer tube 105 is made of a heat-resistant material such as quartz or silicon carbide, etc., for example.

### (Heater)

A heater 106 as a heating mechanism is provided outside of the process tube 103 so as to surround the side wall face of the process tube 103. The heater 106 is configured to generate heat by supply of electric power to a heater wire, and is vertically installed by being supported by a heater base 151 as a holding plate. A temperature sensor 163 as a temperature detector, is installed between the inner tube 104 and the outer tube 105. These heater 106 and temperature sensor 163 are electrically connected to a temperature control sub-controller 202 in the controller part 200 as will be described later.

### (Manifold)

A manifold 109 is disposed in a lower part of the outer tube 105, concentrically with the outer tube 105. The manifold 109 is made of stainless, etc., for example, and is formed into a cylindrical shape, with the upper end and the lower end opened. The manifold 109 is fitted into a lower end portion of the inner tube 104 and a lower end portion of the outer tube 105, to thereby support them. An O-ring 120a as a seal member, is provided between the manifold 109 and the outer tube 105. Although not shown, the process tube 103 is vertically installed on the heater base 151 by supporting the heater base 151 by the manifold 109. A reaction vessel is formed by the process tube 103 and the manifold 109.

### (Silicon-Containing Gas Supply System)

A nozzle 130a for supplying a dichlorosilane (SiH₂Cl₂, abbreviated as DCS) for example as a silicon-containing gas into the processing chamber 101, is provided so as to communicate with an inside of the processing chamber 101. A lower stream end of a gas supply tube 132a is connected to an upper stream end of the nozzle 130a. SiH₂Cl₂ gas supply source 171 being a silicon-containing gas supply source, a valve 162a, a MFC (mass flow controller) 141a being a gas flow control unit, and a valve 161a are provided on the gas supply tube 132a sequentially from an upstream side. A silicon-containing gas supply system is mainly configured by the nozzle 130a, the gas supply tube 132a, the MFC 141a, valves 161a, 162a, and the SiH₂Cl₂ gas supply source 171. A gas control sub-controller 204 in the controller part 200 as will be described later, electrically connected to the MFC 141a, and the valves 161a, 162a.

### (Nitrogen-Containing Gas Supply System)

The nozzle 130b for supplying an ammonia (NH₃) gas for example as the nitrogen-containing gas into the processing chamber 101, is provided in the manifold 109 so as to communicate with the inside of the processing chamber 101. A downstream end of the gas supply tube 132b is connected to an upstream end of the nozzle 130b. A NH₃ gas supply source 172 as a nitrogen-containing gas supply source, a valve 162b, a MFC (mass flow controller) 141b as a gas flow controller unit, and a valve 161b are provided on the gas supply tube 132b sequentially from the upstream side. The nitrogen-containing gas supply system is configured mainly by the nozzle 130b, the gas supply tube 132b, the MFC 141b, valves 161b, 162b, and the NH₃ gas supply source 172. The gas control sub-controller 204 in the controller part 200 described later, is electrically connected to the MFC 141b, and the valves 161b, 162b.

### (Cleaning Gas Supply System)

A gas supply tube 132e for supplying a nitrogen fluoride (NF₃) gas for example as a cleaning gas into the processing chamber 101, is connected to the downstream side of the valve 161a of the gas supply tube 132a. A NF₃ gas supply source 174, a valve 162e, a MFC (mass flow controller) 141e as a gas flow controller unit, and a valve 161e are provided on the gas supply tube 132e sequentially from the upstream side.

Further, a gas supply tube 132f for supplying the nitrogen fluoride (NF₃) gas as the cleaning gas into the processing chamber 101, is connected to the downstream side of the valve 161b of the gas supply tube 132b. The upstream end of the gas supply tube 132f is connected to the upstream side of the valve 162e of the gas supply tube 132e. A valve 162f, a MFC (mass flow controller) 141f as a gas flow controller unit, and a valve 161f are provided on the gas supply tube 132f sequentially from the upstream side.

A cleaning gas supply system is configured mainly by the nozzles 130a, 130b, the gas supply tubes 132a, 132b, 132e, 132f, the MFCs 141e, 242f, valves 161e, 161f, 162e, 162f, and the NF₃ gas supply source 174.

The gas control sub-controller 204 in the controller part 200 described later, is electrically connected to the MFCs 141e, 141f, and the valves 161e, 161f, 162e, 162f.

### (Inert Gas Supply System)

A gas supply tube 132c for supplying a nitrogen (N₂) gas as the inert gas into the processing chamber 101, is connected to the downstream side of the valve 161a of the gas supply tube 132a. A N₂ gas supply source 173, a valve 162c, a MFC (mass flow controller) 141c as a gas flow controller unit, and a valve 161c are provided on the gas supply tube 132c, sequentially from the upstream side.

Further, a gas supply tube 132d for supplying a nitrogen (N₂) gas as the inert gas into the processing chamber 101, is connected to the downstream side of the valve 161b of the gas supply tube 132b. The upstream end of the gas supply tube 132d is connected to the upstream side of the valve 162c of the gas supply tube 132c. A valve 162d, a MFC (mass flow controller) 141d as a gas flow controller unit, and a valve 161d are provided on the gas supply tube 132d sequentially from the upstream side.

An inert gas supply system is configured mainly by the nozzles 130a, 130b, the gas supply tubes 132a, 132b, 132c, 132d, the MFCs 141c, 141d, the valves 161c, 161d, 162c, 162d, and the N₂ gas supply source 173.

The gas control sub-controller 204 in the controller part 200, is electrically connected to the MFCs 141c, 141d, and the valves 161c, 161d, 162c, 162d.

A film-forming gas (source gas) supply system of this embodiment, is configured mainly by the silicon-containing gas supply system and the nitrogen-containing gas supply system. Further, the gas supply system of this embodiment is configured mainly by the silicon-containing gas supply system, the nitrogen-containing gas supply system, and the cleaning gas supply system.

### (Exhaust System)

An exhaust tube 131 for exhausting the inside of the processing chamber 101 is provided in the manifold 109. The exhaust tube 131 is disposed in a lower end part of a cylindrical space 150 formed by a gap between the inner tube 104 and the outer tube 105, so as to communicate with the cylindrical space 150. A vacuum exhaust device 146 such as a vacuum pump, etc., is provided on the downstream side of the exhaust tube 131 (opposite side to a connection side connected to the manifold 109) through a pressure sensor 145 as a pressure detector, and a pressure adjuster 142 such as a variable conductance valve including an APC (Auto Pressure Controller) valve, etc. The vacuum exhaust device 146 is configured to exhaust the inside of the processing chamber 101 so as to be a specific pressure (vacuum degree). A pressure control sub-controller 203 in the controller part 200 described later, is electrically connected to the pressure adjuster 142 and the pressure sensor 145.

With the above-mentioned structure, the silicon-containing gas supplied from the silicon-containing gas supply system, the nitrogen-containing gas supplied from the nitrogen-containing gas supply system, the cleaning gas supplied from the cleaning gas supply system, and the inert gas supplied from the inert gas supply system, rise through the inner tube 104 (through the processing chamber 101) respectively, and are flowed-out to the cylindrical space 150 from an upper end opening of the inner tube 104, and are flowed-down through the cylindrical space 150, and thereafter are exhausted from the exhaust tube 131. The exhaust system of this embodiment is configured mainly by the exhaust tube 131, the pressure adjuster 142, and the vacuum exhaust device 146.

### (Seal Cap)

A lower part of the manifold 109 is air-tightly closed by the seal cap 19 included in the boat elevator 20 of the boat transfer part 12. Namely, the seal cap 19 functions as a furnace throat lid member capable of air-tightly close the lower end opening of the manifold 109, and is configured to abut on the lower end of the manifold 109 from a lower side vertically. The seal cap 19 is made of a metal such as stainless for example, and is formed into a disc-shape. An O-ring 120b as a seal member that abuts on the lower end of the manifold 109 is provided on an upper surface of the seal cap 19.

### (Rotation Mechanism)

A rotation mechanism 154 for rotating the boat 21 is installed in the vicinity of a center part of the seal cap 10 and on the opposite side to the processing chamber 101. A rotary axis 155 of the rotation mechanism 154 passes through the seal cap 19 and supports the boat 21 from below. The rotation mechanism 154 is configured to rotate the wafer 7 by rotating the boat 21.

### (Boat Elevator)

The seal cap 19 is configured to be vertically elevated by the boat elevator 20 as a substrate holder elevating mechanism which is vertically installed outside of the process tube 103. By elevating the seal cap 19, the boat 21 can be transferred to/from the processing chamber 101. The mechanical control sub-controller 205 in the controller part 200 described later, is electrically connected to the rotation mechanism 154 and the boat elevator 20.

### (Shutter)

Further, a furnace throat shutter 147 as a second furnace throat lid member capable of air-tightly closing the lower end opening of the manifold 109, is provided in the lower part of the manifold 109. The shutter 147 is abutted on the lower end of the manifold 109 after unloading the boat 21 from the processing chamber 101 by an elevating and turning motion, so as to air-tightly close the inside of the processing chamber 101 after unloading the boat 21. An O-ring 120c as a seal member abutted on the lower end of the manifold 109, is provided on the upper surface of the shutter 147.

### (3) Structure of the Controller

A processing operation of the substrate processing apparatus 1 thus constituted, is controlled by an instruction from the controller part 200. The controller part 200 may be disposed in the casing 2 of the substrate processing apparatus 1, or may be installed separately from the casing 2 of the substrate processing apparatus 1 and may be electrically connected thereto via a communication line, etc.

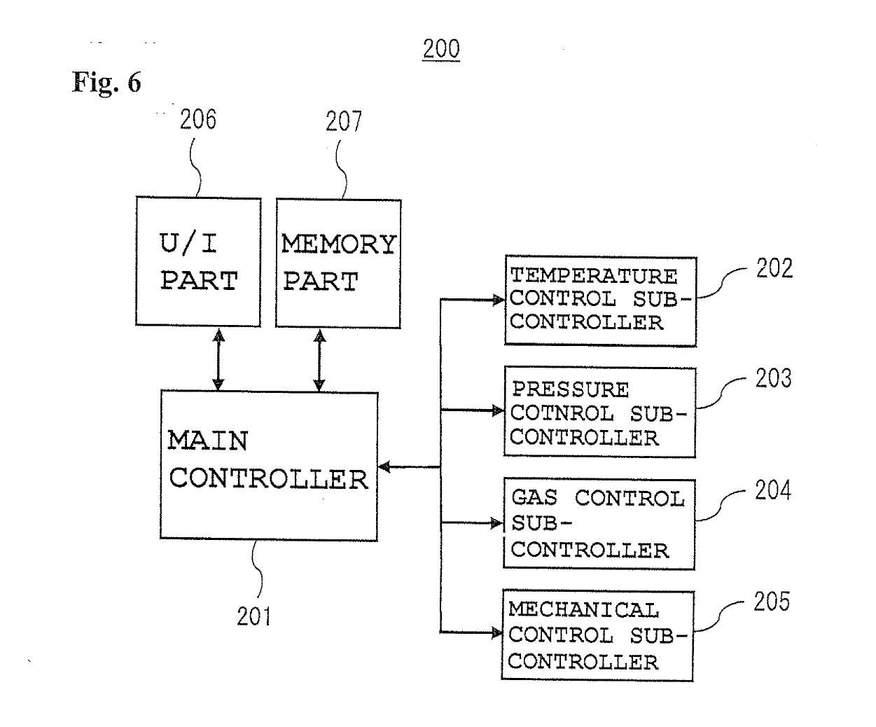

The structure of the controller part 200 of this embodiment will be described hereafter based on the drawings. FIG. 6 is a block diagram showing the controller part 200 of the substrate processing apparatus 1 according to a first embodiment of the present invention.

As shown in FIG. 6, the controller part 200 includes a main controller 201 and a plurality of sub-controllers 202, 203, 204, and 205 which are constructed by computers. Each computer here executes a program to perform information processing based on an instruction of the program, and is specifically constituted by a combination of CPU (Central Processing Unit), memory, and an input/output device, etc. As the sub-controller, the temperature control sub-controller 202, the pressure control sub-controller 203, the gas control sub-controller 204, and the mechanical control sub-controller 205, can be given.

The temperature control sub-controller 202 is configured to control a power supply condition to the heater 106 based on temperature information detected by the temperature sensor 163 at a desired timing, so that the temperature in the processing chamber 101 has a desired temperature distribution.

The pressure control sub-controller 203 is configured to control the pressure adjuster 142 at a desired timing based on the pressure information detected by the pressure sensor 145, so that the pressure in the processing chamber 101 has a desired pressure.

The gas control sub-controller 204 is configured to control a gas flow rate supplied into the processing chamber 101. More specifically, the gas control sub-controller 204 is configured to control each of the MFC 141a, and valves 161a, 162a, so that the flow rate of the silicon-containing gas supplied into the processing chamber 101 is a specific flow rate respectively at a specific timing. Further, the gas control sub-controller 204 is configured to control each of the MFC 141b, and valves 161b, 162b, so that the flow rate of the nitrogen-containing gas supplied into the processing chamber 101 is a specific flow rate respectively at a specific timing. Further, the gas control sub-controller 204 is configured to control each of the MFCs 141e, 141f, and valves 161e, 161f, 162e, 162f so that the flow rate of the cleaning gas supplied into the processing chamber 101 is a specific flow rate respectively at a specific timing. Further, the gas control sub-controller 204 is configured to control each of the MFCs 141c, 141d, and valves 161c, 161d, 162c, 162d so that the flow rate of the inert gas supplied into the processing chamber 101 is a specific flow rate respectively at a specific timing.

The mechanical control sub-controller 205 is configured to control the wafer transfer part 11, the boat transfer mechanism 30, the boat elevator 20, and the rotation mechanism 154, etc., to perform a desired operation at a desired timing.

Each of the sub-controllers 202, 203, 204, and 205 is electrically connected to the main controller 201 via the communication line for example. The main controller 201 is configured to perform control of each of the sub-controllers 202, 203, 204, 205, namely to perform an overall control of the substrate processing apparatus 1. The control part (control unit) of this embodiment is configured mainly by the main controller 201 and each of the sub-controllers 202, 203, 204, and 205.

Further, a user interface (abbreviated as “U/I” hereafter) part 206 and a memory part 207 are connected to the main controller 201, other than the above-mentioned each of the sub-controllers 202, 203, 204, and 205.

The U/I part 206 includes an output device such as a display device, etc., and an input device such as a touch panel, etc., so as to display and output contents of a recipe (such as an item name and a numerical value of a control parameter, etc.) and a progress state, etc., of substrate processing, for a user (operator), and is configured to receive input of the information from the user. An operation part (operation unit) of this embodiment is configured mainly by the U/I part 206.

The memory part 207 includes a memory device such as a hard disc device, etc., and is configured to store each kind of program and recipe, etc., required for the operation of the substrate processing apparatus 1. Note that the recipe stored in the memory part 207 includes a maintenance recipe for perform cleaning to the inside of the processing chamber 101, other than the recipe in which a processing procedure and a processing condition for substrate processing are defined. For example, a gas cleaning recipe or a purge cleaning recipe, etc., are stored in the memory part 207 as the maintenance recipe.

### (4) Substrate Processing Method

A substrate processing method executed using the substrate processing apparatus 1 of this embodiment will be described next. Here, a case of executing a substrate processing step being one of the steps of manufacturing a semiconductor device, is given as an example. Further, in executing the substrate processing step, as shown in FIG. 1, the substrate processing apparatus 1 includes two boats 21 (these boats are called “first boat 21a” and “second boat 21b” so as to be identifiable.), which are placed on each of the TR stage 5 and the ES stage 6 respectively.

In executing the substrate processing step, first, the recipe corresponding to the substrate processing to be executed, is read from the memory part 207, and is developed into the memory such as RAM (Random Access Memory), etc., in the controller part 200. Then, an operating instruction is given to each of the sub-controllers 202, 203, 204, 205 from the main controller 201 as needed. Thus, the executed substrate processing step roughly includes a transferring step, a loading step, a film forming step, a boat transferring step, and an unloading step.

### (Transferring Step)

When the first boat 21a placed on the TR stage 5 is an empty boat, a drive instruction of the wafer transfer part 11 is given to the mechanical control sub-controller 205 from the main controller 201. Then, the wafer transfer part 11 starts transfer processing of the wafer 7 onto the first boat 21a on the TR stage 5 from the pod 50 on the supplying/receiving stage 8, while following the instruction from the mechanical control sub-controller 205. The transfer processing is performed until charge of all wafers 7 scheduled to be charged onto the boat 21 (wafer charge) is completed.

### (Loading Step)

When specified number of wafer 7 is charged onto the first boat 21a on the TR stage 5, the first boat 21a is transferred to the BL stage 4 from the TR stage 5, by a lower arm 31 of the boat transfer mechanism 30 which is operated according to the instruction from the mechanical control sub-controller 205, and is transferred on the seal cap 19 in the boat elevator 20. Then, after transfer of the first boat 21a, the lower arm 31 is returned to the TR stage 5.

Thereafter, the first boat 21a is elevated by the boat elevator 20 which is operated according to the instruction from the mechanical control sub-controller 205, and is loaded into the processing chamber 101 formed in the inner tube 104 of the processing furnace 13. When the first boat 21a is completely loaded into the processing chamber 101, the lower end of the manifold 109 of the processing furnace 13 is air-tightly closed by the cap 19 of the boat elevator 20.

At this time, the inside of the processing chamber 101 is purged by supply of the N₂ gas, according to the instruction from the gas control sub-controller 204. Namely, by opening the valves 162, 161c, 152d, and 161d, the N₂ gas supplied into the gas supply tubes 132c, 132d from the N₂ gas supply source 173, is controlled to a specific flow rate by the MFCs 141c, 141d, and thereafter is supplied into the processing chamber 101 from the nozzles 130a, 130b through the gas supply tubes 132a, 132b. Note that supply of the N₂ gas into the processing chamber 101 is continued until all substrate processing steps are ended.

### (Film Formation Step)

Thereafter, the inside of the processing chamber 101 is vacuum-exhausted by the vacuum exhaust device 146 to a specific film formation pressure (vacuum degree) according to the instruction from the pressure control sub-controller 203. At this time, the pressure in the processing chamber 101 is measured by the pressure sensor 145, and based on the measured pressure information, the pressure adjuster 142 is feedback-controlled. Further, the inside of the processing chamber 102 is heated by the heater 106 to a specific temperature according to the instruction from the temperature control sub-controller 202. At this time, the power supply condition to the heater 106 is feedback-controlled so that the temperature of the inside of the processing chamber 101 is a specific temperature (film formation temperature), based on the temperature information detected by the temperature sensor 163. Subsequently, the rotation of the first boat 21a and the wafer 7 by the rotation mechanism 154 is started, while following the instruction from the mechanical control sub-controller 205.

When the inside of the processing chamber 101 is maintained to a specific film formation temperature and a specific film formation pressure, supply of the SiH₂Cl₂ gas as the silicon-containing gas and the NH₃ gas as the nitrogen-containing gas into the processing chamber 101, is started, while following the instruction from the gas control sub-controller 204. Namely, the SiH₂Cl₂ gas supplied into the gas supply tube 132a from the SiH₂Cl₂ gas supply source 171 by opening the valves 162a, 161a, is controlled to a specific flow rate by the MFC 141a, and thereafter passes through the gas supply tube 132a, and is supplied into the processing chamber 101 from the nozzle 130a. Further, the NH₃ gas supplied into the gas supply tube 132b from the gas supply source 172 by opening the valves 162b, 161b is controlled to a specific flow rate by the MFC 141b, and thereafter passes through the gas supply tube 132b, and is supplied into the processing chamber 101 from the nozzle 130b.

At this time, the N₂ gas supplied into the processing chamber 101 functions as a diluting gas for diluting the film-forming gas (SiH₂Cl₂ gas and NH₃ gas), or as a carrier gas for promoting a dispersion into the processing chamber 101. By controlling the supply flow rate of the N₂ gas, concentration and dispersion rate of the film-forming gas (SiH₂Cl₂ gas and NH₃ gas) can be controlled.

The film-forming gas (SiH₂Cl₂ gas and NH₃ gas) supplied into the processing chamber 101, rises through the inner tube 104 (through the processing chamber 101), and is flowed-out to the cylindrical space 150 from the upper end opening of the inner tube 104, and is flowed-down through the cylindrical space 150, and is exhausted from the exhaust tube 131. The film-forming gas (SiH₂Cl₂ gas and NH₃ gas) is brought into contact with a surface of the wafer 7 when passing through the processing chamber 101. At this time, a thin film, namely a silicon nitride film (Si₃N₄ film, simply called a SiN film hereafter) is deposited on the surface of the wafer 7 by a thermal CVD reaction. When the silicon nitride film having a specific film thickness is formed after elapse of a previously set processing time, the valves 162a, 161a, 162b, and 161b are closed, to thereby stop the supply of the film-forming gas (SiH₂Cl₂ gas and NH₃ gas) into the processing chamber 101.

Then, the inside of the processing chamber 101 is purged, by exhausting the inside of the processing chamber 101 while continuing the supply of the N₂ gas into the processing chamber 101, with the valves 162, 161c, 162d, 161d opened. When the atmosphere of the inside of the processing chamber 101 is substituted with the N₂ gas, an opening degree of the pressure adjuster 142 is adjusted so that the pressure in the processing chamber 101 is returned to a normal pressure. Further, the power supply to the heater 106 is stopped so that the temperature in the processing chamber 101 is decreased to a specific temperature (wafer unloading temperature).

### (Boat Transfer Step)

The second boat 21b is transferred onto the TR stage 5 from the ES stage 6 by the boat transfer mechanism 30, according to the instruction from the mechanical control sub-controller 205, during film-forming step applied to the first boat 21a.

At this time, when the second boat 21b transferred onto the TR stage 5 is an empty boat, the transfer step is performed to the second boat 21b. Namely, the wafer 7 of the pod 50 on the supplying/receiving stage 8, is transferred to the second boat 21b on the TR stage 5 by the wafer transfer part 11. However, when the processed wafer 7 is held by the second boat 21b, transfer of a new unprocessed wafer 7 to the second boat 21b is performed after the processed wafer 7 is discharged from the second boat 21b and is transferred on the pod 50.

### (Unloading Step)

When the film-forming step applied to the first boat 21a is completed, thereafter the rotation of the first boat 21a and the wafer 7 by the rotation mechanism 154 is stopped according to the instruction from the mechanical control sub-controller 205, to thereby make the seal cap 19 descend by the boat elevator 20 and open the lower end of the manifold 109 and unload the first boat 21a holding the processed wafer 7 to the outside of the process tube 103 (boat unload).

Then, the first boast 21a holding the processed wafer 7 is immediately transferred to the ES stage 6 from the BL stage 4 by the boat transfer mechanism 30, while following the instruction from the mechanical control sub-controller 205. After being transferred, the first boat 21a placed on the ES stage 6 in a high temperature state, is extremely effectively cooled by the clean air 15 blown-out from the clean unit 3. Then, when being cooled to 150° C. or less for example, the first boat 21a is transferred onto the TR stage 5 from the ES stage 6 by the boat transfer mechanism 30. Note that at this time, the transfer of the unprocessed wafer 7 onto the second boat 21b on the TR stage 5, should be completed, and the loading of the second boat 21b into the processing chamber 101 (boat load) should also be completed.

By repeating above-mentioned each step, the substrate processing apparatus 1 of this embodiment can form the silicon nitride film on the wafer 7 with high throughput.

### (5) Maintenance Method of the Substrate Processing Apparatus

An object of the above-mentioned film-forming step is to form a film on the wafer 7. However, actually, the film is also formed on an inner wall of the inner tube 104 and the boat 21, etc., other than the wafer 7. When the formed film is deposited thick, an added stress is increased to generate a crack, thus allowing foreign matters (particles) to be generated in the processing chamber 101. Therefore, the substrate processing apparatus 1 of this embodiment executes a cleaning step described below, as a maintenance step for a maintenance of the inside of the processing chamber 101, when the thickness of the deposited film in the processing chamber 101 reaches a specific thickness by repeating the above-mentioned film-forming step.

### (Cleaning Step)

Execution of the cleaning step is started at a point when the thickness of the deposition (piled film thickness) adhered to the inside of the processing chamber 101 reaches a specific thickness before generation of peel-off and drop of the deposition. Whether or not the piled film thickness reaches a specific thickness, can be judged from a piled film thickness value detected by a film thickness detector provided in the processing chamber 101 formed by the process tube 103 as a reaction tube, or can be judged based on a film thickness estimated value estimated from the number of times of use or a using time, etc., in the use of the processing chamber 101 for the film-forming step. Namely, maintenance timing is judged by the controller part 200, using at least one setting parameter selected from the piled film thickness value inside of the process tube 103, etc., and the number of times of use and the using time of the process chamber 101, and by comparing the setting parameter with a specific threshold value.

In executing the cleaning step, first, the maintenance recipe for cleaning to be executed is read from the memory part 207, and is developed into the memory such as RAM in the main controller 201. Then, an operation instruction is given to each of the sub-controllers 202, 203, 204, 205 from the main controller 201 as needed. Thus, the cleaning step is executed. Note that in the cleaning step, the maintenance recipe such as a gas cleaning recipe or a purge cleaning recipe, etc., is executed.

### (Gas Cleaning Recipe)

When the gas cleaning recipe is executed in the cleaning step, the lower end opening of the manifold 109 is air-tightly closed by the shutter 147 for example. Then, the inside of the processing chamber 101 is vacuum-exhausted by the vacuum exhaust device 146 so that the pressure in the processing chamber 101 is a specific cleaning pressure (vacuum degree), and the inside of the processing chamber 101 is heated by the heater 106 so that the temperature in the processing chamber 101 is a specific cleaning temperature.

Thereafter, the supply of the NF₃ gas as a cleaning gas into the processing chamber 101, is started in a state that the inside of the processing chamber 101 is maintained to a specific cleaning temperature and is maintained to a specific cleaning pressure. The NF₃ gas supplied into the gas supply tubes 132e, 132f from the NF₃ gas supply source 174 by opening the valves 162e, 161e, 162f, 161f, is controlled to a specific flow rate by the MFCs 141e, 141f, and thereafter passes through the gas supply tubes 132a, 132b, and is supplied into the processing chamber 101 from the nozzles 130a, 130b.

At this time, the N₂ gas supplied into the processing chamber 101 functions as a diluting gas for diluting the NF₃ gas being the cleaning gas, or as a carrier gas for promoting the dispersion of the above NF₃ gas into the processing chamber 101. By controlling the supply flow rate of the N₂ gas, concentration and dispersion rate of the NF₃ gas can be controlled.

The NF₃ gas supplied into the processing chamber 101 rises through the inner tube 104 (through the processing chamber 101), and is flowed-out to the cylindrical space 150 from the upper end opening of the inner tube 104, and is flowed-down through the cylindrical space 150, and is exhausted from the exhaust tube 131. The NF₃ gas is brought into contact with the piled silicon nitride film, etc., when passing through the processing chamber 101, to thereby remove the silicon nitride film, etc., by a thermal chemical reaction. Namely, the heated and activated NF₃ gas becomes etching species, to thereby remove the silicon nitride film, etc., piled inside of the processing chamber 101, by etching. Note that in this embodiment, the nozzles 130a, 130b for supplying the film-forming gas into the processing chamber 101, is used as the nozzles for supplying the NF₃ gas into the processing chamber 101. With this structure, the silicon nitride film deposited inside of the nozzles 130a, 130b can also be effectively removed. When a previously set processing time is elapsed, and removal of the silicon nitride film, etc., is completed, the valves 162c, 161c, 162d, 161d are closed, to thereby stop the supply of the NF₃ gas into the processing chamber 101.

Then, the inside of the processing chamber 101 is purged by exhausting the inside of the processing chamber 101 while continuing the supply of the gas into the processing chamber 101, with the valves 162c, 161c, 162d, 161d opened.

Note that the cleaning recipe in this embodiment is a kind of an exemplary recipe, and the cleaning gas and a film kind, etc., are not limited to the above-mentioned content. Further, the above-mentioned gas cleaning recipe may be executed in either case of not loading the boat 21 into the processing chamber 101, or loading the empty boat 21 (boat 21 not holding the wafer 7) into the processing chamber 101. However, when the continuous batch processing is performed, the transfer of the wafers 7 is performed as described later, and therefore it is preferable to execute the gas cleaning recipe in a state of not loading the boat 21 into the processing chamber 101.

### (Purge Cleaning Recipe)

Based on the method of processing a wafer 7 in the above-mentioned embodiment, the purge cleaning recipe is executed if the film-forming process is performed using the film-forming gas (SiH₂Cl₂ gas and NH₃ gas), under a condition of a film-formation processing temperature: 730° C. to 800° C., with the SiN film (Si₃N₄ film) formed on the silicon wafer of φ300 mm, and particularly the film thickness: 1500 Å (150 nm) or more. Note that the gas cleaning recipe and the purge cleaning recipe as maintenance recipes, are suitably selected by the controller part 200. For example, these recipes may also be selected according to the piled film thickness, an apparatus structure (for example, presence/absence of a forcible cooling mechanism), and presence/absence of the boat 21 in the processing chamber 101, etc. Further, when there is a necessity for performing maintenance, and the cleaning step is executed according to the necessity, which of the gas cleaning recipe and the purge cleaning recipe is used, can be selected based on an operation content in the U/I part 206 of the controller part 200.

In parallel to cooling and discharging of the wafer 7 (wafer discharge), gas purge is performed using the inert gas in an atmosphere state of the inside of the air-tightly closed processing chamber 101. For example, purge is performed by the N₂ gas. When the purge cleaning is performed (when the purge cleaning recipe is executed), the lower end opening of the manifold 109 is air-tightly closed by the shutter 147 for example. Then, the inside of the processing chamber 101 is preferably exhausted through a high flow vent line not shown provided by being diverged from a main exhaust line, while supplying a large flow rate of the N₂ gas of 20 L/min or more for example. In this case, a main valve is closed.

Simultaneously with an in-furnace purge in this atmosphere state, the temperature in the processing chamber 101 is decreased by the forcible cooling mechanism at a larger temperature decrease rate than a decrease rate (≈3° C./min) at a natural cooling time, thus causing a rapid temperature variation in the furnace. Thus, a stress of the deposited film adhered to the inside of the processing chamber 101, is more increased than that of the natural cooling time, to thereby positively generate a thermal stress, and generate a forcible crack on the deposited film, which is the crack larger than that of the natural cooling time. Fine particles dispersed by the generation of the crack, are forcibly and effectively discharged to the outside of the processing chamber 101 by such an in-furnace purge performed in the atmosphere state. When the in-furnace temperature is decreased by the forcible cooling mechanism, an atmosphere gas of a high temperature is exhausted by an exhaust blower not shown, and air and a cooling medium such as N₂, etc., is introduced into a heat insulating cover not shown by an introducing blower not shown.

The temperature decrease rate is set to at least 10° C./rain, and is preferably set to 20° C./rain. Regarding the decrease of the in-furnace temperature, the temperature in the apparatus 1 is decreased to at least about ½ (50%) of the film-formation temperature. Namely, a width (amount) in decrease of the temperature is set to at least about ½ (50%) of the film-formation temperature. For example, when the film-formation temperature is about 730 to 800° C., the temperature in the processing chamber 101 is decreased to 400° C. from 800° C.

When performing an experiment of purge while slowly decreasing the in-furnace temperature to 400° C. from 800° C. without performing the forcible cooling (rapid cooling), it is found that the crack is not generated so much on the deposited film adhered to the inside of the furnace, and the effect is insufficient. Namely, it is found that the sufficient effect cannot be obtained only by making a large difference in the temperature (a large difference in decrease of the temperature). In order to obtain the sufficient effect, both of the (1) difference in the temperature (width in decrease of the temperature) and (2) temperature decrease rate, are required to be large.

The gas purge of the inside of the processing chamber 101 using the inert gas performed simultaneously with the forcible cooling of the inside of the furnace, has a merit that a particle removal effect is larger in a case that the gas purge is performed in the atmosphere state, compared with a case that the gas purge is performed in a depressurization state. Further, in a case of a depressurizing purge, the step of returning the in-furnace atmosphere to the atmospheric pressure after purge is required, thus causing a loss of time. However, in a case of an atmospheric purge, the above-mentioned step is not required, and there is a merit that the time can be shortened. Further, in the case of the depressurizing purge, a by-product adhered to the exhaust system and a circumference thereof is sublimed and flows backward in some cases. However, in the case of the atmospheric purge, such a fault is not generated.

In a case of not purging the inside of the furnace but performing only the forcible cooling, the generated particles drop on a furnace throat gate valve 13. The particles that drop on the furnace throat gate valve are retreated to a retreat position outside of the furnace while being held on the furnace throat gate valve 13, when the next film-formation is performed. Namely, when the next film-formation is performed, the inside of the furnace can be set in a non-existence state of particles, thus not affecting the next processing. Note that a groove (recess) is provided on the upper surface of the furnace throat gate valve 13, and the dropped particles can be received by this groove. Therefore, when the furnace throat gate valve 13 is moved to the retreat position 14, drop of the particles can be prevented. Also, a particle removing mechanism (suction unit, etc.) is provided at the retreat position 14, and the particles on the furnace throat gate valve may be removed while the furnace throat gate valve is retreated.

A series of the operation of purging the inside of the processing chamber 101 by the inert gas in the atmospheric pressure state, while decreasing the temperature in the processing chamber 101 to about ½ of the film-formation temperature at a temperature decrease rate of at least 10° C./min or more and preferably 20° C./min or more, is performed by controlling the heater 5, the forcible cooling device, the gas supply system, and the exhaust system, etc., by the main controller 201. The in-furnace purge thus performed is called a low temperature purge or LTP.

In this embodiment, a preferable temperature increase rate during increase of the temperature before decrease of the in-furnace temperature in LTP, is 3° C./min or more and preferably 10 to 100° C./rain, and further preferably 30 to 100° C./min. Further, a preferable temperature decrease rate during decrease of the in-furnace temperature is 3° C./min, and more preferably 10 to 100° C./min, and further preferably 20 to 100° C./min.

After LTP, the in-furnace temperature is adjusted to 600° C. before boat-loading, to thereby shorten the in-furnace temperature increasing time after boat-loading in the next film formation, thereby shortening a total film-formation time. After LTP, if the in-furnace temperature is maintained to 400° C. being a temperature at an end point of the drop of the LTP, the boat-loading is required at 400° C. in the next film-formation, and thereafter the in-furnace temperature is required to be increased by 360° C. from 400° C. to 760° C., thus prolonging the temperature increasing time. If the in-furnace temperature is maintained to 600° C. after LTP, it is sufficient to perform boat-loading at 600° C. in the next film-formation, and thereafter increase the in-furnace temperature only by 160° C. from 600° C. to 760° C., thus making it possible to shorten the temperature increasing time. Note that when the in-furnace temperature during boat-loading is excessively high, there is a fault that a leap of the wafer 7 occurs. Therefore, the in-furnace temperature is maintained to 600° C. in consideration of such a fault.

In the above-mentioned processing of the wafer 7, the atmospheric pressure is exhausted in an atmospheric N₂ purging state of the inside of the processing chamber 101, with the processing chamber 101 air-tightly closed after boat-unloading (with no wafer 7 in the processing chamber 101). In parallel, the in-furnace temperature is decreased (reduced) at a temperature decrease rate of 20° C./min or more to 400° C. from 800° C. by the forcible cooling mechanism. By performing such a temperature decreasing process, the stress of the film on which the reaction by-product adhered to the inner surface of the processing chamber 101 is deposited, is more increased than a case of the natural cooling (temperature decrease rate≈3° C./min), to thereby positively generate the thermal stress and generate a forcible crack on the deposited film, which is the crack larger than the crack in the natural cooling. Further, by purging the inside of the processing chamber 101 by the atmospheric gas purge, the fine particles dispersed by generation of the crack, are forcibly and effectively discharged to the outside of the processing chamber 101.

The in-furnace temperature during film-formation is higher than the temperature at the end point of the temperature decrease in LTP (400° C. in this embodiment) by several-hundreds degrees, and the stress of the deposited film that has undergone the temperature decreasing process (400° C.) once, is relaxed. Therefore, generation of a new crack is prevented during SiN film-formation in the next batch processing. Further, it is found that the stress of the deposited film is reduced when the temperature is high, and the stress of the deposited film is in a reduced state in the film-formation process, and therefore possibility of generating the new crack is further reduced in the film-formation process.

Thus, the crack of the deposited film is generated, and the fine particles caused by the generation of the crack are forcibly discharged to the outside of the processing chamber 101 before boat-loading, and therefore wafer processing without fine particles can be performed. Further, the particles generated by the crack of the deposited film, can be effectively removed, and therefore cleaning of the processing chamber 101 may be performed before peel-off of the deposited film occurs. Moreover, a period until the deposited film is peeled-off can be considerably extended by this embodiment, and therefore an interval between cleaning times for cleaning the processing chamber 101 can be considerably extended (until the film thickness of the deposited film becomes 25 μm).

Note that coefficients of thermal expansion of SiC and SiN are close to each other, thus not generating the difference in the stress between SiC and SiN. Therefore, when the reaction tube such as outer tube 105 and inner tube 104, etc., is made of SiC, the effect of LTP cannot be expected so much. Meanwhile, there is a large difference in the coefficients of thermal expansion between SiO₂ (quartz) and SiN, and therefore there is also a large difference in the stress between SiO₂ and SiN. Namely, LTP is particularly effective in a case of performing the film-formation of the SiN film, using the reaction tube made of quartz.

As described above, according to the LTP of this embodiment, the crack is forcibly generated on the generated deposited film in the processing chamber 101 before the film-formation process, and the fine particles caused by the generation of the crack is discharged. Therefore, the generation of the fine particles can be suppressed during film-formation, thus making it possible to perform the film-formation process with high quality, and cleaning of the reaction furnace may be executed before the deposited film is peeled-off. Therefore, the interval between cleaning times is prolonged, and both of a maintenance ratio and an operating ratio can be improved.

Note that similarly to the gas cleaning recipe, the purge cleaning recipe of this embodiment is a kind of exemplary recipe, and the difference in temperature and the temperature decrease rate and the N₂ flow rate, etc., are not limited to the above-mentioned content. Also, similarly to the gas cleaning recipe, the purge cleaning recipe may be executed in either case of not loading the boat 21 into the processing chamber 101, or loading the empty boat 21 (boat 21 not holding the wafer 7) into the processing chamber 101. However, the purge cleaning recipe of this embodiment is preferably executed in a state of not loading the boat 21 into the processing chamber 101.

### (6) Substrate Transfer Method in Maintenance

Incidentally, when the above-mentioned cleaning step is executed in the substrate processing apparatus 1 including the first boat 21a and the second boat 21b, as described above, if the transfer of the wafers 7 is inhibited for the incoming batch, an unnecessary operation and a waiting time, etc., are generated, irrespective of including the first boat 21a and the second boat 21b, thus involving a risk that the throughput is poor as a result, in the processing applied to the wafer 7.

Thus, the substrate processing apparatus 1 of this embodiment performs a processing operation of a procedure described below, when the maintenance needs to be performed to the inside of the processing chamber 101, etc., namely when the above-mentioned cleaning step is executed thereto.

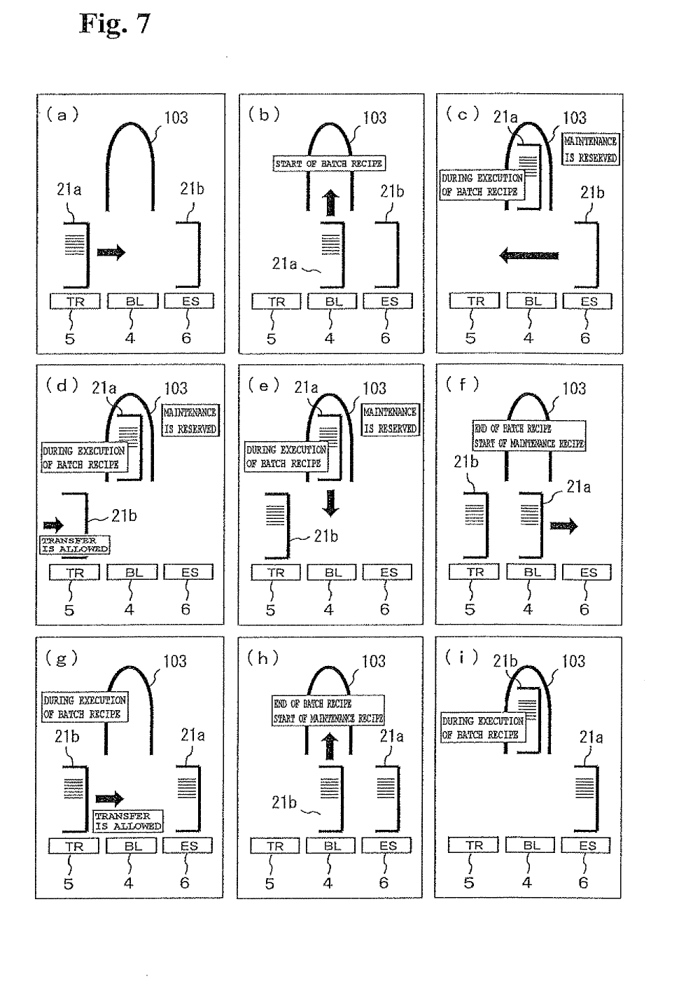

FIG. 7 is an explanatory view showing a substrate transfer method performed in the substrate processing apparatus of the first embodiment.

In a stage before execution of the cleaning step is generated, as shown in FIG. 7A, the first boat 21a is transferred onto the BL stage 4 from the TR stage 5, when there is the wafer-charged first boat 21a on the TR stage 5. At this time, there is the second boat 21b being an empty boat on the ES stage 6.

Then, as shown in FIG. 7B, after transfer of the first boat 21a to the BL stage 4, the first boat 21a is loaded into the process tube 103 as the reaction tube, and a batch recipe is started. Namely, the film-formation step is performed to the wafer 7 held by the first boat 21a in the processing chamber 101 formed by the process tube 103 in a state that the first boat 21a holding the wafer 7 for a certain batch is loaded into the process tube 103, based on the batch recipe read by the main controller 201.

As shown in FIG. 7C, the second boat 21b is transferred to the TR stage 5 during execution of the batch recipe performed to the first boat 21a. Here, when there is a necessity for executing the cleaning step when the piled film thickness of the deposition adhered to the inside of the processing chamber 101, etc., reaches a specific thickness, during execution of the batch recipe performed to the first boat 21a, a flag is erected for indicating “maintenance is reserved” under control of the main controller 201. The “maintenance is reserved” means a state that the maintenance recipe can be immediately executed after end of the batch recipe being executed. By erecting such a flag, under control of the main controller 201, information regarding the “maintenance is reserved” is outputted to the U/I part 206, and a user (operator) is notified of this matter. Note that although not shown, the processing chamber 101 is air-tightly closed by the seal cap 19.

However, even in a case of the “maintenance is reserved”, the main controller 201 allows the transfer of the wafers 7 to the boat 21, without inhibiting such a transfer. Therefore, even in a case that the batch recipe is being executed and the maintenance is reserved, the wafer 7 is transferred and charged into the second boat 21b when there is the second boat 21b being the empty boat on the TR stage 5 as shown in FIG. 7D. Namely, even in a case that the maintenance is performed not to the incoming batch after end of the present batch, the transfer of the wafers 7 for the incoming batch is performed to the second boat 21b.

Thereafter, when the film-formation step performed to the first boat 21a is ended, as shown in FIG. 7E, the first boat 21a holding the processed wafer 7 is unloaded to the outside of the process tube 103.

Then, as shown in FIG. 7F, the first boat 21a holding the processed wafer 7 is transferred to the ES stage 6 from the BL stage 4. Thus, the batch recipe being executed at present is ended. Further, the maintenance is immediately performed to the process tube 103 being the reaction tube, etc., after end of the present batch, because the flag indicates the “maintenance is reserved”. In performing maintenance, the main controller 201 reads the maintenance recipe and executes the cleaning step while following the read maintenance recipe.

The maintenance recipe read at this time, is the recipe for mainly performing maintenance of the process tube 103 being the reaction tube, and loading of the empty boat is not required. Therefore, even when the maintenance recipe is being executed, the main controller 201 allows the transfer of the boat 21 without inhibiting its transfer. Specifically, as shown in FIG. 7G, when there is the second boat 21b in which the wafer is charged onto the TR stage 5, this second boat 21b is transferred to the BL stage 4 from the TR stage 5. Namely, the second boat 21b is transferred to the BL stage 4 after end of the maintenance, so as to immediately execute the incoming batch. Note that in the cleaning step performed at this time, loading of the empty boat is not required, and although not shown, the lower end opening of the manifold 109 is air-tightly closed by the shutter 147.

Thereafter, when the cleaning step performed to the process tube 103 is ended, as shown in FIG. 7H, the second boat 21b holding the wafer 7 for the incoming batch is charged into the process tube 103 as the reaction tube.

Then, as shown in FIG. 7I, execution of the batch recipe is started in a state that the second boat 21b is loaded into the process tube 103. Namely, the film-formation step is performed to the wafer 7 for the incoming batch held by the second boat 21b, in the processing chamber 101 formed by the process tube 103, based on the batch recipe read by the main controller 201.

(7) Effect of this Embodiment

According to this embodiment, one or more effects given below can be exerted.

(a) According to this embodiment, even when the maintenance is performed after end of the present batch in a case of the “maintenance is reserved”, the wafer 7 is charged into the empty boat 21 without inhibiting the transfer of the wafers 7 to the empty boat 21 on the TR stage 5. Then, the maintenance is immediately performed to the process tube 103 at a timing of the maintenance after end of the present batch, without loading the empty boat 21 into the process tube 103. Further, the boat 21 in which the wafer 7 of the incoming batch is charged, is transferred to the BL stage at a boat load position during execution of the maintenance. Namely, transfer of the wafers of the incoming batch is performed even at a timing of performing maintenance of the process tube 103 during execution of the continuous batch processing, and the incoming batch is immediately executed after end of the maintenance performed to the process tube 103 without loading the empty boat 21 after end of the present batch. Accordingly, even in a case that there is a necessity for performing maintenance during the execution of the continuous batch processing, processing can be immediately performed to the incoming batch after performing maintenance, and therefore an unnecessary operation and a waiting time, etc., are not generated, thus improving the throughput compared with a case that the substrate transfer is inhibited during execution of the maintenance.
(b) According to this embodiment, the maintenance is performed to the process tube 103 at a timing of performing maintenance, without loading the empty boat 21 into the process tube 103. Accordingly, even when improving the throughput using two boats of the first boat 21a and the second boat 21b for one process tube 103, namely even when the number of the boats 21 is larger than the number of process tubes 103, execution of an unnecessary (namely, excessive) maintenance to each boat 21a, 21b can be omitted. Therefore, life of each boat 21a, 12b can be prolonged, compared with a case that the loading of the empty boat 21 is always required.

### Second Embodiment of the Present Invention

A second embodiment of the present invention will be described next.

The substrate processing apparatus 1 of this embodiment is different from that of the above-mentioned first embodiment, in following point described for the controller part 200.

In the controller part 200, both of a tube maintenance recipe and a boat maintenance recipe are held in the memory part 207, as the maintenance recipe for performing the cleaning step. As described in the first embodiment, the tube maintenance recipe is the recipe for performing maintenance of the process tube 103, without loading the empty boat 21 into the process tube 103. Meanwhile, the boat maintenance recipe is the recipe for performing maintenance of both of the process tube 103 and the empty boat 21 in a state of loading the empty boat 21 into the process tube 103, which is the recipe used conventionally. Further, these tube maintenance recipe and boat maintenance recipe include both of the gas cleaning recipe and the purge cleaning recipe in the memory part 207.

Further, since the memory part 207 includes both of the tube maintenance recipe and the boat maintenance recipe, the controller part 200 is configured to select either one of the maintenance recipes when maintenance is required and the cleaning step is executed as needed. Further, the controller part 200 is configured to select and execute the maintenance recipe selected from the gas cleaning recipe and the purge cleaning recipe.

Judgment of the necessity for the maintenance, namely judgment regarding the timing of the maintenance, may be performed by monitoring the piled film thickness of each part of both of the process tube 103 and the boat 21, and judging whether or not either one of the piled film thicknesses reaches a specific thickness. Specifically, it can be considered that the maintenance timing is judged by comparing at least one setting parameter with a specific threshold value, using at least one setting parameter selected from the piled film thickness value, the number of times of use, and the using time of the process tube or the boat 21.

Further, which of the maintenance recipes is used, may be selected based on an operation content operated by the U/I part 206 of the controller part 200. Specifically, if selection information regarding selecting which of the maintenance recipes is used, is inputted from the U/I part 206 and stored in the memory part 207, either one of the maintenance recipes is selected to be used by reading the stored selection information from the memory part 207.

However, the controller part 200 may also be configured to switch the selection regarding which of the maintenance recipes is used, when the maintenance timing arrives. Specifically, the controller part 200 monitors the piled film thickness value, etc., regarding each of the process tube 103 and the boat 21, then displays and outputs its monitoring result on the U/I part 206, so that the selection of the maintenance recipes can be switched from the tube maintenance recipe to the boat maintenance recipe, or from the boat maintenance recipe to the tube maintenance recipe, according to the piled film thickness value, etc., of each displayed and outputted part.

In this case, the piled film thickness value, etc., is monitored for each of the process tube 103 and the boat 21. However, the setting parameter such as the piled film thickness value, etc., may be selected individually for each of the process tube 103 and the boat 21. Specifically, for example, it can be considered that the piled film thickness value is used as the setting parameter for the process tube 103, and the number of times of use and the using time, etc., are used as the setting parameters for the boat 21, to thereby judge the maintenance timing in each case. Further, even when the same setting parameter is used in each case, it can also be considered that the maintenance timing can be judged using a threshold value set to different values in the process tube 103 and the boat 21 for example. In each case, which of the setting parameters is used, can be selected individually by the operation of the U/I part 206.

The substrate processing apparatus 1 having the above-mentioned structure, is capable of exerting one or more effects given below, in addition to the effect described in the above-mentioned case of the first embodiment.

(c) According to this embodiment, both of the tube maintenance recipe and the boat maintenance recipe are held, and which of the maintenance recipes is used, can be selected when the maintenance is performed. Accordingly, even when the piled film thickness values are different in the process tube 103 and the boat 21 during execution of the continuous batch processing, a suitable maintenance recipe is executed, and the generation of particles due to a damage of a component (the process tube 103 or the boat 21) by over-etching in the cleaning step, can be suppressed.
(d) According to this embodiment, the selection content of which of the maintenance recipes is used, can be switched at the maintenance timing. Accordingly, the user (operator) who references monitoring information regarding which portion allows abnormality such as piled film thickness to be generated, can switch the maintenance recipe to be executed, according to the content of the monitoring information. As a result, execution of a suitable maintenance recipe can be ensured.
(e) According to this embodiment, the setting parameter used for judging the maintenance timing, can be selected individually for each of the process tube 103 and the boat 21. Accordingly, different setting parameters can be used in the process tube 103 and the boat 21. Therefore, a free degree can be given in setting a selection reference regarding which of the tube maintenance recipe and the boat maintenance recipe is used. As a result, execution of a suitable maintenance recipe is further ensured.

### Third Embodiment of the Present Invention

A third embodiment of the present invention will be described next, with reference to the drawings.

Similarly to the above-mentioned case of the second embodiment, the substrate processing apparatus 1 of this embodiment is configured to select which of the tube maintenance recipe and the boat maintenance recipe is used. However, unlike the case of the second embodiment, the selection is automatically performed by the controller part 200.

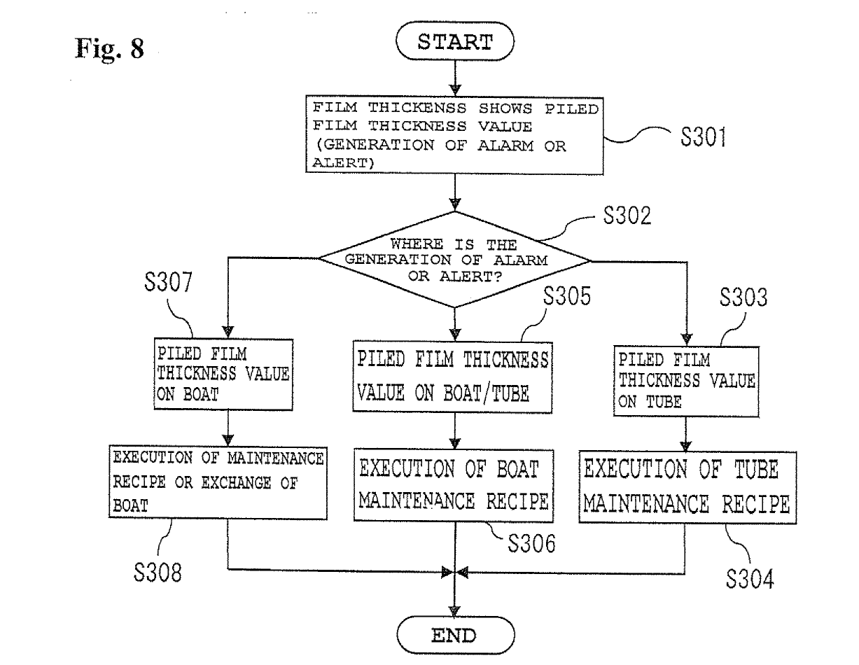

FIG. 8 is a sequence flow chart showing an execution procedure of a maintenance recipe monitoring program in the substrate processing apparatus 1 according to a third embodiment of the present invention.

When each kind of the recipes represented by the recipe for substrate processing is executed, the main controller 201 in the controller part 200 reads the maintenance recipe monitoring program from the memory part 207 corresponding the each kind of the recipes, and execution of the maintenance recipe monitoring program is started. When the maintenance recipe monitoring program is started, as shown in FIG. 8, the main controller 201 monitors the piled film thickness value, etc., of each part of both of the process tube 103 and the boat 21. Then, as a result of monitoring, when either one of the piled film thickness values reaches a specific threshold value, error (abnormality) processing for the piled film thickness value, etc., is performed (step 301, the step is abbreviated as “S” hereafter). Namely, the main controller 201 so judges that the necessity for executing the cleaning step is generated, and erects the flag indicating the “maintenance is reserved”, and outputs error information accordingly (alarm information or alert information) to the user (operator) from the U/I part 206.

Thereafter, the main controller 201 judges a generation part of the alarm or the alert at a timing of executing the cleaning step (S302).

When the generation part of the alarm or the alert is the process tube 103 (S303), the main controller 201 so judges that the maintenance is required for the process tube 103, but the maintenance is not required for the boat 21. Then, the tube maintenance recipe is read from the memory part 207 to perform maintenance for the process tube 103 without loading the empty boat 21, and the tube maintenance recipe is executed (S304).

When the generation part of the alarm or the alert is both of the process tube 103 and the boat 21 (S305), the main controller 201 so judges that the maintenance is required for both of the process tube 103 and the boat 21. Then, the boat maintenance recipe is read from the memory part 207 to perform maintenance for both of the process tube 103 and the empty boat 21, with the empty boat 21 loaded, and the boat maintenance recipe is executed (S306).

When the generation part of the alarm or the alert is the boat 21 (S307), the main controller 201 so judges that the maintenance is required at least for the boat 21. Then, the boat maintenance recipe is read from the memory part 207 to perform maintenance for both of the process tube 103 and the boat 21, with the boat 21 loaded, and the boat maintenance recipe is executed (S308). Note that when the generation part of the alarm or the alert is the boat 21 (S307), the main controller 201 so judges that the maintenance is not required for the boat 21 but exchange of the boat 21 is required if the piled film thickness values, etc., are largely different between the process tube 103 and the boat 21, and outputs the error information accordingly to the user (operator) from the U/I part 206.

The substrate processing apparatus 1 having the above-mentioned structure, can exert one or more effects given below, in addition to the above-described effects of the second embodiment.

(f) According to this embodiment, by executing the maintenance recipe monitoring program, which of the tube maintenance recipe and the boat maintenance recipe is used for performing maintenance, is automatically selected, according to the abnormality generation part in the piled film thickness value. Accordingly, a suitable maintenance recipe can be executed according to the abnormality generation part in the piled film thickness without generating a human selection error, etc., and the selection of the maintenance recipe can be speedily and surely performed.

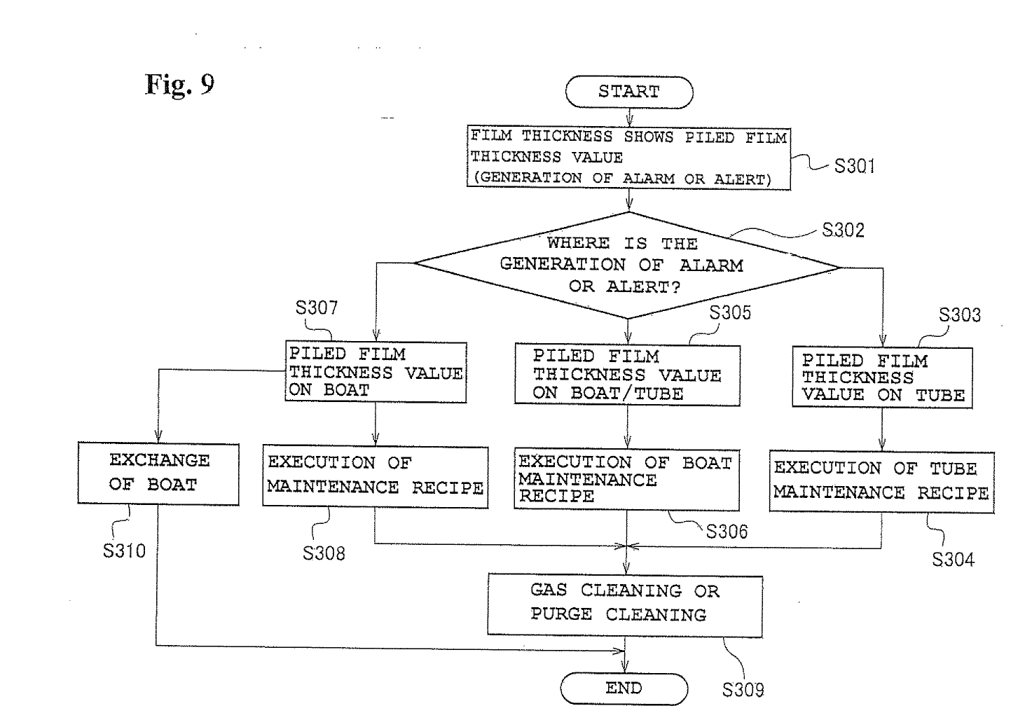

FIG. 9 is a sequence flow chart showing an execution procedure of the maintenance recipe monitoring program in the substrate processing apparatus 1 according to a fourth embodiment of the present invention.

Similarly to the case of the above-mentioned second embodiment or the third embodiment, the substrate processing apparatus 1 of this embodiment is configured to select which of the tube maintenance recipe and the boat maintenance recipe is used. However, unlike the second or the third embodiment, the gas cleaning recipe is further executed or the purge cleaning recipe is further executed, or its selection is automatically performed by the controller part 200.

When each kind of the recipes represented by the recipe for substrate processing is executed, the main controller 201 in the controller part 200 reads the maintenance recipe monitoring program from the memory part 207 based on the each kind of the recipes, and execution of this maintenance recipe monitoring program is started. When the maintenance recipe monitoring program is started, as shown in FIG. 9, the main controller 201 monitors the piled film thickness value, etc., of each part of both of the process tube 103 and the boat 21. Then, as a result of monitoring, when either one of the piled film thickness values reaches a specific threshold value, error (abnormality) processing for the piled film thickness value, etc., is performed (step 301, the step is abbreviated as “S” hereafter). Namely, the main controller 201 so judges that the necessity for executing the cleaning step is generated, and erects the flag indicating the “maintenance is reserved”, and outputs error information accordingly (alarm information or alert information) to the user (operator) from the u/I part 206.

Thereafter, the main controller 201 judges the generation part of the alarm or the alert at a timing of executing the cleaning step (S302).

When the generation part of the alarm or the alert is the process tube 103 (S303), the main controller 201 so judges that the maintenance for the process tube 103 is required, but the maintenance for the boat 21 is not required. Then, the tube maintenance recipe is read from the memory part 207 to perform maintenance for the process tube 103 without loading the empty boat 21, and the tube maintenance recipe is executed (S304). Then, the processing is moved to the next step.

When the generation part of the alarm or the alert is both of the process tube 103 and the boat 21 (S305), the main controller 201 so judges that the maintenance is required for both of the process tube 103 and the boat 21. Then, the boat maintenance recipe is read from the memory part 207 to perform maintenance for both of the process tube 103 and the empty boat 21, with the empty boat 21 loaded, and the boat maintenance recipe is executed (S306). Then, the processing is moved to the next step.

When the generation part of the alarm or the alert is the boat 21 (S307), the main controller 201 so judges that the maintenance is required for at least the boat 21. Then, the maintenance recipe is read from the memory part 207, to perform maintenance for both of the process tube 103 and the boat 21, with the boat 21 loaded therein, and the boat maintenance recipe is executed (S308). Then, the processing is moved to the next step. Note that when the generation part of the alarm or the alert is the boat 21 (S307), the main controller 201 so judges that not the maintenance for the boat 21 but the exchange of the boat 21 is required if the piled film thickness values are largely different between the process tube 103 and the boat 21 (S310), and the error information is outputted accordingly from the U/I information part 206, so that the user (operator) is notified of the error information. Finally, either one of the gas cleaning recipe and the purge cleaning recipe is selected (S309) in the next step of the step 304 (S304), step 306(S306), and step 308(S308).

The substrate processing apparatus 1 having the above-mentioned structure can exert one or more effects given below, in addition to the effect described in the second or third embodiment.

(g) According to this embodiment, which of the tube maintenance recipe and the boat maintenance recipe is used when performing the maintenance, is automatically selected according to the abnormality generation part of the piled film thickness value, by executing the maintenance recipe monitoring program, and next, either the gas cleaning recipe or the purge cleaning recipe is automatically selected according to the generation part of the alarm or the alert. Accordingly, a suitable maintenance recipe is executed according to the abnormality generation mode of the piled film thickness and the generation part of the alarm or the alert, and the selection of the maintenance recipe can be speedily and surely performed.

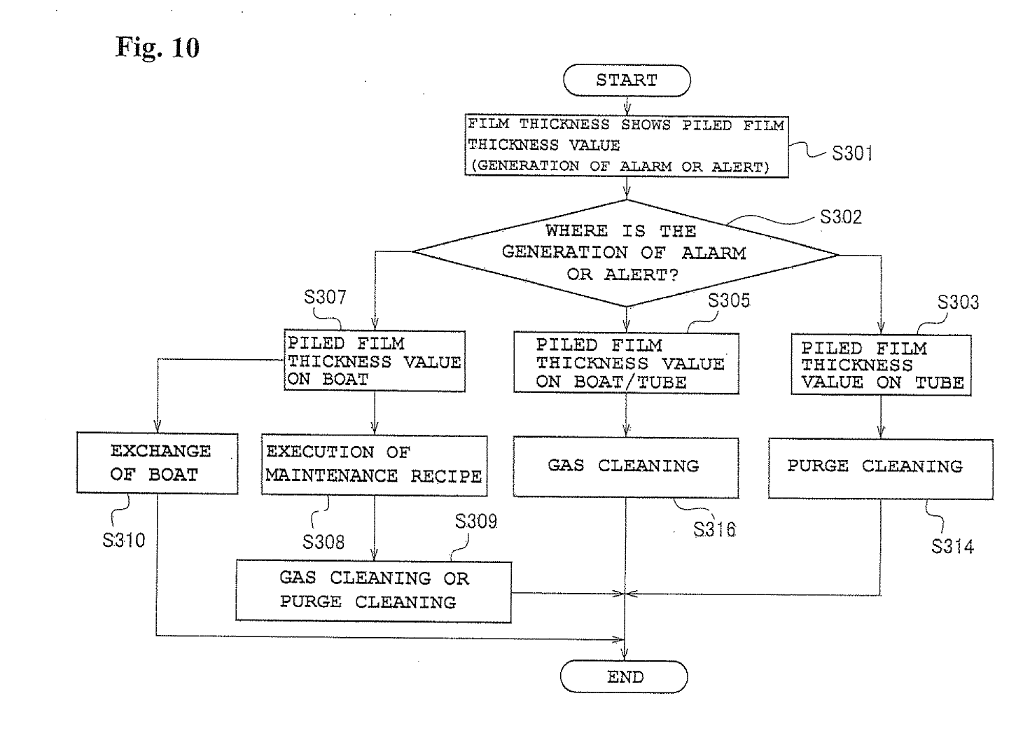

FIG. 10 is a sequence flow chart showing the execution procedure of the maintenance recipe monitoring program in the substrate processing apparatus 1 according to a modified example of the fourth embodiment of the present invention.

Similarly to the case of the fourth embodiment, the substrate processing apparatus 1 of this embodiment is configured to select either one of the tube maintenance recipe and the boat maintenance recipe. However, unlike the case of the fourth embodiment, the controller part 200 is configured to automatically select the execution of the recipes so that the gas cleaning recipe is executed as the boat maintenance recipe, and the purge cleaning recipe is executed as the tube maintenance recipe. Also, the controller part 200 is configured to automatically select which of the recipes of the gas cleaning recipe (boat maintenance recipe) and the purge cleaning recipe (tube maintenance recipe) is executed as the maintenance recipe.

When each kind of the recipes represented by the recipe for substrate processing is executed, the main controller 201 in the controller part 200 reads the maintenance recipe monitoring program from the memory part 207 corresponding to the each kind of the recipes, and execution of the maintenance recipe monitoring program is started. When the maintenance recipe monitoring program is started, as shown in FIG. 10, the main controller 201 monitors the piled film thickness value, etc., of each part of both of the process tube 103 and the boat 21. Then, as a result of monitoring, when either one of the piled film thickness values reaches a specific threshold value, error (abnormality) processing for the piled film thickness value, etc., is performed (step 301, the step is abbreviated as “S” hereafter). Namely, the main controller 201 so judges that the necessity for executing the cleaning step is generated, and erects the flag indicating the “maintenance is reserved”, and outputs error information accordingly (alarm information or alert information) to the user (operator) from the U/I part 206.

Thereafter, the main controller 201 judges the generation part of the alarm or the alert at a timing of executing the cleaning step (S302).

When the generation part of the alarm or the alert is the process tube 103 (S303), the main controller 201 so judges that the maintenance for the process tube 103 is required, but the maintenance for the boat 21 is not required. Then, the tube maintenance recipe is read from the memory part 207 to perform maintenance for the process tube 103 without loading the empty boat 21, and the tube maintenance recipe is executed (S314).

When the generation part of the alarm or the alert is both of the process tube 103 and the boat 21 (S305), the main controller 201 so judges that the maintenance is required for both of the process tube 103 and the boat 21. Then, the boat maintenance recipe is read from the memory part 207 to perform maintenance for both of the process tube 103 and the empty boat 21, with the empty boat 21 loaded, and the boat maintenance recipe is executed (S316).

When the generation part of the alarm or the alert is the boat 21 (S307), the main controller 201 so judges that the maintenance is required for at least the boat 21. Then, the maintenance recipe is read from the memory part 207, to perform maintenance for both of the process tube 103 and the boat 21, with the boat 21 loaded therein, and the boat maintenance recipe is executed (S308). Then, the processing is moved to the next step. Note that when the generation part of the alarm or the alert is the boat 21 (S307), the main controller 201 so judged that not the maintenance for the boat 21 but the exchange of the boat 21 is required if the piled film thickness values are largely different between the process tube 103 and the boat 21 (S310), and the error information is outputted accordingly to the user (operator) from the U/I information part 206, so that the user (operator) is notified of the error information. Next, either one of the gas cleaning recipe and the purge cleaning recipe is selected (S309) in the next step of the step 308 (S308).

The substrate processing apparatus 1 having the above-mentioned structure can exert one or more effects given below, in addition to the effect described in a case of the fourth embodiment.

(h) According to this embodiment, which of the tube maintenance recipe and the boat maintenance recipe is used when performing the maintenance, is automatically selected according to the abnormality generation part of the piled film thickness value, by executing the maintenance recipe monitoring program, and next, either the gas cleaning recipe or the purge cleaning recipe is automatically selected according to the generation part of the alarm or the alert. Accordingly, a suitable maintenance recipe is executed according to the abnormality generation mode of the piled film thickness and the generation part of the alarm or the alert, and the selection of the maintenance recipe can be speedily and surely performed.

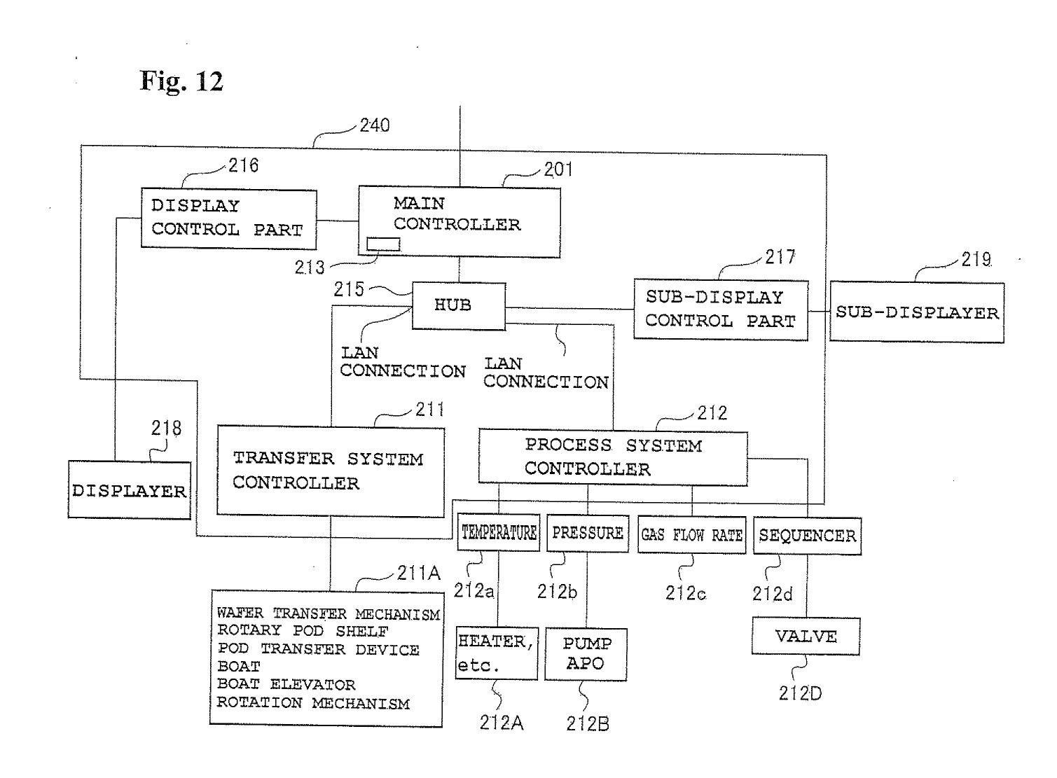

FIG. 12 is a sequence flow chart showing the execution procedure of the maintenance recipe monitoring program in the substrate processing apparatus 1 of the fifth embodiment of the present invention.

Similarly to the case of the fourth embodiment, the substrate processing apparatus 1 of this embodiment is configured to select either one of the tube maintenance recipe and the boat maintenance recipe. However, unlike the case of the fourth embodiment, when the piled film thickness error is generated in both of the boat and the tube, the controller part 200 is configured to judge whether the maintenance is required according to each importance of the piled film thickness error, and automatically select which of the tube maintenance recipe and the boat maintenance recipe is used. Specifically, when the exchange of the boat is required, the controller part 200 is configured to automatically perform the purge cleaning recipe (tube maintenance recipe) as the maintenance recipe, and when the exchange of the boat is not required, the controller part 200 is configured to automatically perform the gas cleaning recipe (boat maintenance recipe) as the maintenance recipe. When the exchange of the tube is required, the controller part 200 is configured not to execute the maintenance recipe, because a maintenance work is required to be performed irrespective of the piled film thickness of the boat.

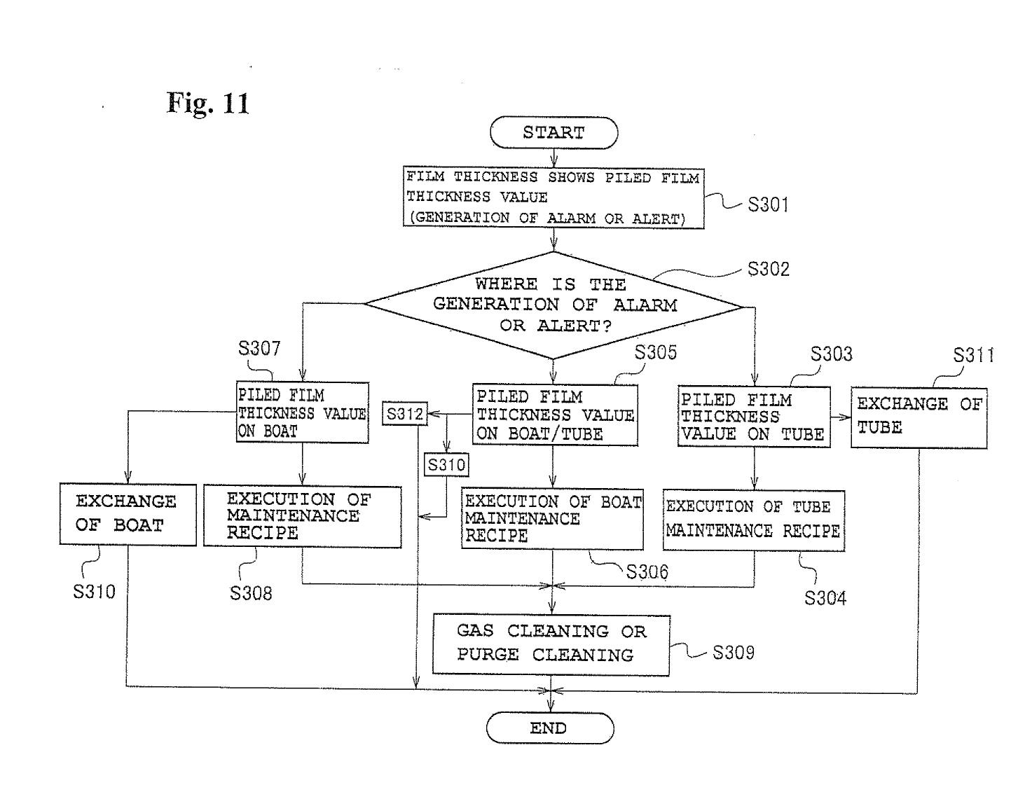

When each kind of the recipes represented by the recipe for substrate processing is executed, the main controller 201 in the controller part 200 reads the maintenance recipe monitoring program from the memory part 207 based on the each kind of the recipes, and execution of the maintenance recipe monitoring program is started. When the maintenance recipe monitoring program is started, as shown in FIG. 11, the main controller 201 monitors the piled film thickness, etc., of each part of both of the process tube 103 and the boat 21. Then, as a result of monitoring, when either one of the piled film thickness values reaches a specific threshold value, error (abnormality) processing for the piled film thickness value, etc., is performed (step 301, the step is abbreviated as “S” hereafter). Namely, the main controller 201 so judged that the necessity for executing the cleaning step is generated, and erects the flag indicating the “maintenance is reserved”, and outputs error information accordingly (alarm information or alert information) to the user (operator) from the u/I part 206.

Thereafter, the main controller 201 judges the generation part of the alarm or the alert at a timing of executing the cleaning step (S302).

When the generation part of the alarm or the alert is the process tube 103 (S303), the main controller 201 so judges that the maintenance for the process tube 103 is required, but the maintenance for the boat 21 is not required. Then, the tube maintenance recipe is read from the memory part 207 to perform maintenance for the process tube 103 without loading the empty boat 21, and the tube maintenance recipe is executed (S314). Further, the controller part 200 is configured to automatically perform the selection of the recipes whether the gas cleaning recipe is executed or the purge cleaning recipe is executed (S309). Meanwhile, when the generation part of the alarm is the process tube (S303), the main controller 201 so judges that the maintenance recipe cannot be executed, and urges the exchange of the process tube 103. For example, error message urging the exchange of the process tube 103 is outputted to the user (operator) from the U/I part 206. At this time, the user preferably performs the exchange of the boat 21 simultaneously.

When the generation part of the alarm or the alert is both of the process tube 103 and the boat 21 (S305), the main controller 201 so judges that the maintenance is required for both of the process tube 103 and the boat 21. Then, the boat maintenance recipe (gas cleaning recipe) is read from the memory part 207 to perform maintenance for both of the process tube 103 and the empty boat 21, with the empty boat 21 loaded, and the boat maintenance recipe is executed (S306). In this case, when the generation part of the alarm is the process tube 103 (S305), the main controller 201 so judges that the maintenance recipe cannot be executed, and urges the exchange of the process tube 103 and the boat 21. For example, error message urging the exchange of the process tube 103 is outputted to the user (operator) from the U/I part 206 (S312). When the generation part of the alarm is the boat 21, and the generation part of the alert is the process tube 103 (S305), the main controller 201 so judges that the maintenance recipe cannot be executed, and urges the exchange of the boat 21. For example, the error message urging the exchange of the boat 21 is outputted to the user (operator) from the U/I part 206 (S310). Meanwhile, the main controller 201 so judges that the maintenance is required for the process tube 103. Then, the boat maintenance recipe is read from the memory part 207, to perform maintenance for the process tube 103, with the empty boat 21 not loaded therein, and the boat maintenance recipe is executed (S306). Further, the controller part 200 is configured to automatically perform the execution or selection of the recipes, whether the gas cleaning recipe is executed or the purge cleaning recipe is executed (S309).

When the generation part of the alarm or the alert is the boat 21 (S307), the main controller 201 so judges that the maintenance is required for at least the boat 21. Then, the boat maintenance recipe is read from the memory part 207 to perform maintenance for both of the process tube 103 and the boat 21, with the boat 21 loaded therein, which is the boat 21 in which the alarm or the alert is generated, and the boat maintenance recipe is executed (S308). Then, the processing is moved to the next step. Note that when the generation part of the alarm or the alert is the boat 21 (S307), the main controller 201 so judges that not the maintenance for the boat 21 but the exchange of the boat 21 is required if the piled film thickness values are largely different between the process tube 103 and the boat 21 (S310), and the error information is outputted accordingly to the user (operator) from the U/I information part 206, so that the user (operator) is notified of the error information. Next, either one of the gas cleaning recipe and the maintenance recipe is selected (S309) in the next step of the step 308 (S308) as the maintenance recipe. This case is the same as the case of the fourth embodiment.

The substrate processing apparatus 1 having the above-mentioned structure can exert one or more effects given below, in addition to the effect described in the case of the fourth embodiment.

(i) According to this embodiment, which of the tube maintenance recipe and the boat maintenance recipe is used when performing the maintenance, is automatically selected according to the importance of the abnormality and abnormality contents of the piled film thickness value, by executing the maintenance recipe monitoring program, and for example, either the gas cleaning recipe or the purge cleaning recipe is automatically selected according to the generation part of the alarm or the alert. Accordingly, a suitable maintenance work and a suitable maintenance recipe are executed according to the abnormality generation mode of the piled film thickness and the generation part of the alarm or the alert, and the selection of the maintenance recipe can be speedily and surely performed.

For example, an example of controlling the processing operation in the substrate processing apparatus 1 by the controller part 200, is given in the above-mentioned embodiments (the first embodiment to the fifth embodiment). However, a control function in the controller part 200 can be realized by a specific program for making a computer function as the control part (control unit) and the operation part (operation unit) described in the above-mentioned embodiment. In this case, the specific program is used by being installed in the memory part 207 of the controller part 200. However, the specific program may be provided via a communication line connected to the controller part 200, or may be provided by being stored in a recording medium readable by the controller part 200.

### Other Embodiment of the Present Invention

FIG. 12 is a block diagram showing a controller part 300 in the substrate processing apparatus 1 according to other embodiment of the present invention, wherein a distribution system is configured.

Next, a structure of a control device 340 focusing on the controller part 300 as a main control part, will be described with reference to FIG. 12. As shown in FIG. 12, a device controller 340 as a control device includes the control part 300; a switching hub 315 connected to the controller part 300; a display control part 316 connected to the controller part 300; a sub-display control part 317 as a sub-operation part connected to the controller part 300; a transfer system controller 311 as a transfer control part; and a process system controller 312 as a process control part. For example, a transfer system controller 311 and a process system controller 312 are electrically connected to the controller part 300 by LAN (Local Area Network) such as 100BASE-T, etc., via the switching hub 315.

A port 313 is provided in the controller part 300, as a mounting part into/from which a USB memory, etc., being a recording medium as an external memory device is inserted and removed. OS corresponding to the port 313 is installed in the controller part 300. Further, the controller part 300 is connected to an external host computer not shown, via a communication network for example. Therefore, even when the substrate processing apparatus 1 is installed in the clean room, the host computer can be disposed in an office, etc., outside of the clean room.

The display control part 316 is connected to a displayer 318 by a video cable for example. The displayer 318 is a liquid crystal display panel for example. The displayer 318 being a display part is configured to display each operation screen for operating the substrate processing apparatus 1. Then, the display control part 316 displays the information generated in the substrate processing apparatus 1 on the display part through the operation screen. Further, the information displayed on the display part is outputted to a device such as a USB memory inserted into the main controller 201. The display control part 316 receives input data (input instruction) inputted by a worker from the operation screen displayed on the displayer 318, and the input data is transmitted to the controller part 300. Further, the display control part 316 receives the recipe developed into a memory (RAM), etc., described later or an instruction (control instruction) for executing an arbitrary substrate process recipe (also called a process recipe) out of a plurality of recipes stored in the memory part as will be described later, which are then transmitted to the controller part 300. Note that the display control part 316, the input part, and the displayer 318 may be configured by a touch panel. Further, the sub-display control part 317 and the sub-displayer 319 have the same structures as the structures of the display control part 316 and the displayer 318. Here, the display control part 316 and the sub-display control part 317 are described as separate bodies from the main controller 201. However, they may be included in the controller part 300. Further, the operation part according to the embodiment of the present invention may be configured by at least the controller part 300, the display control part 316, and the displayer 318.

The transfer system controller 211 is connected to a substrate transfer system 211A mainly configured by a rotary pod shelf, a boat elevator, a pod transfer device (substrate container transfer device), a wafer transfer mechanism (substrate transfer mechanism), the boat 21 and a rotation mechanism (not shown). The transfer system controller 211 is configured to control each transfer operation of the rotary pod shelf, the boat elevator, the pod transfer device (substrate container transfer device), the wafer transfer mechanism (substrate transfer mechanism), the boat 21, and the rotation mechanism.

The process system controller 212 includes a temperature controller 212a, a pressure controller 212b a gas supply flow controller 212c, and a sequencer 212d. The temperature controller 212a, the pressure controller 212b, the gas supply flow controller 212c and the sequencer 212d constitute a sub-controller, and are electrically connected to the process system controller 212. Therefore, transmission/reception of each data and download/upload of each file are enabled. Note that although the process system controller 212 and the sub-controller are shown as separate bodies in the figure, they may be constituted as one body.

A heating mechanism 212A mainly configured by a heater and a temperature sensor, is connected to the temperature controller 212a. The temperature controller 212a is configured to adjust a temperature in the processing chamber 101 by controlling the temperature of the heater in the processing chamber 101. Note that the temperature controller 212a is configured to control switching (on/off) of a thyristor, and control a power supplied to a heater wire.

A gas exhaust mechanism 212B mainly configured by an APC valve as a pressure valve and a vacuum pump, is connected to the pressure controller 212b. The pressure controller 212b is configured to control an opening degree of the APC valve and the switching (on/off) of the vacuum pump, so that the pressure in the processing chamber 101 is a desired pressure at a desired timing, based on a pressure value detected by the pressure sensor.

The gas flow controller 212c is configured by MFC (Mass Flow Controller). The sequencer 212d is configured to control the supply and stop of the gas from the processing gas supply tube and the purge gas supply tube, by opening and closing a valve 212D. Further, the process system controller 212 is configured to control the gas flow controller 212c (MFC) and the sequencer 212d (valve 212D) so that the flow rate of the gas supplied into the processing chamber 29 is a desired flow rate at a desired timing.

Thus, in this embodiment, the controller part 300, the transfer system controller 311, and the process system controller 312 constitute a controller structure distributed for each function. Thus, for example, even if the transfer system controller 311 becomes abnormal, the controller part 300 and the process system controller 312 are not stopped even if being controlled by the process system controller 312, because they are independent systems, and can be executed in this state. Accordingly, even if a transfer error is generated during processing a substrate, a apparatus stop does not occur, thus eliminating a case of lot-out. Transfer of a substrate and processing of a substrate are controlled by the controller part 200 heretofore, thus enlarging a load and a large volume of data cannot be treated. However, owing to a process miniaturization at present, data volume has been increased year by year, and in order to respond to such a trend, a distribution type controller of this embodiment is preferable.

Note that the controller part 300, the transfer system controller 311, and the process system controller 312 of this embodiment can be realized using a normal computer system, not depending on a dedicated system. For example, each controller for executing a specific processing can be configured by installing a program for making a general purpose computer execute the above-mentioned processing from a recording medium (such as a flexible disc, CD-ROM and USB) in which the program is stored.

Then, means for supplying these programs are optional. As described above, the program may be supplied via a communication line, a communication network, and a communication system for example, other than the supply of the program via a specific recording medium as described above. In this case, for example, the program is displayed in a display board of the communication network, which is then superimposed on a transfer wave via the network. Then, the program thus provided is started, and under the control of OS, by executing the program similarly to other application program, a specific processing can be executed.

As described above, an embodiment of the present invention is specifically described. However, the present invention is not limited to each of the above-mentioned embodiment, and can be variously modified in a range not departing from the gist of the invention.

For example, the above-mentioned embodiment of the present invention gives an example of a case that the substrate to be processed is a semiconductor wafer substrate. However, the present invention is not limited thereto, and can be suitably applied to the substrate processing apparatus for processing a glass substrate such as LCD (Liquid Crystal Display), etc.

Further, for example, the above-mentioned embodiment of the present invention givens an example of forming a film of Si-system as a processing performed by the substrate processing apparatus 1. However, the present invention is not limited thereto. Namely, the processing performed by the substrate processing apparatus may be the processing of forming an oxide film and a nitride film, or may be the processing of forming a film containing metal. Further, a specific content of substrate processing is not a problem, and the present invention can be applied not only to the film formation processing, but also to other substrate processing such as annealing, oxidizing, nitriding, dispersing and lithography, etc. Further, the present invention can be suitably applied to other substrate processing apparatus such as an annealing apparatus, an oxidation apparatus, a nitriding apparatus, an exposure apparatus, a coating apparatus, a drying apparatus, a heating apparatus, and a CVD apparatus utilizing plasma, or the like.

Further, for example, when the boat maintenance recipe is executed in the embodiment of the present invention, this is executed in a state that the empty boat 21 with not wafer 7 charged therein, is loaded into the process tube 103. However, the present invention is not limited thereto, and for example, the boat maintenance recipe may be executed in a state that the boat 21 with dummy wafer charged therein, is loaded into the process tube 103. In addition, the present invention can also be applied, when executing the cleaning recipe for the supply tube such as a nozzle for supplying gas, and the exhaust tube for exhausting the gas.

Further, for example, in the cleaning step according to the embodiment of the present invention, the nitrogen fluoride (NF₃) gas is continuously supplied into the processing chamber 101. However, the present invention is not limited thereto, and the NF₃ gas may be supplied intermittently for multiple numbers of times.

Further, for example, the DCS (SiH₂Cl₂) gas is given for example as the silicon-containing gas. However, the present invention is not limited thereto, and for example, other chlorosilane-system such as monochlorosilane (SiH₃Cl, abbreviated as MCS), hexachlorodisilane (Si₂Cl₆, abbreviated as HCDS), tetrachlorosilane (SiCl₄, abbreviated as STC), trichlorosilane (SiHCl₃, abbreviated as TCS), and inorganic raw materials such as trisilane (Si₃H₈, abbreviated as TS), disilane (Si₂H₆, abbreviated as DS), and monosilane (SiH₄, abbreviated as MS), etc., and organic raw materials such as aminosilane-based tetradimethyl aminosilane (Si[N(CH₃)₂]₄, abbreviated as 4DMAS), trisdimethyl aminosilane (Si[N(CH₃)₂]₃H, abbreviated as 3DMAS), bisdiethyl aminosilane (Si[N(C₂H₅)₂]₂H₂, abbreviated as 2DEAS), bistertiary butyl aminosilane (SiH₂[NH(C₄H₉)]₂, abbreviated as BTBAS), etc., can be used.

Further, for example, the ammonia (NH₃) gas is given for an example as the nitrogen-containing gas. However, the present invention is not limited thereto, and for example, nitrogen monoxide (NO) gas and nitrogen dioxide (NO₂) gas, etc., may be used, and a combination of these gases may also be used.

Further, for example, the nitrogen trifluoride (NF₃) gas is given for example as the cleaning gas. However, the present invention is not limited thereto, and for example a halogen-containing gas containing halogen such as fluorine (F) and chlorine (Cl) including hydrogen fluoride (HF) gas, chlorine trifluoride (ClF₃) gas, and fluorine (F₂) gas, may be used, and a combination of these gases may also be used.

Further, for example, the nitrogen (N₂) gas is given for example, as the inert gas. However, the present invention is not limited thereto, and for example rare gases such as helium (He) gas, neon (Ne) gas, and argon (Ar) gas, etc., may be used, and a combination of the nitrogen gas and these rare gases may also be used.

Further, for example as described above, the processing furnace 13 of the present invention is configured as the batch type apparatus for processing a plurality of wafers 7. However, the present invention is not limited thereto, and the present invention may also be applied to a single wafer type apparatus for processing the wafer 7 one by one.

Further, as described above for example, the processing furnace 13 of the present invention is configured to form a silicon nitride (SiN) film on the surface of the wafer 7 by the thermal CVD reaction. However, the present invention is not limited thereto, and can be applied to a structure of forming the silicon nitride (SiN) film on the surface of the wafer 7 using plasma.

### Preferable Aspects of the Present Invention

Preferable aspects of the present invention will be described hereafter.

### [Supplementary Description 1]

According to a first aspect of the present invention, there is provided a substrate processing apparatus, including:

an operation part configured to select a maintenance recipe for a reaction tube used for substrate processing, and a maintenance recipe for both of the reaction tube and a substrate holder loaded in the reaction tube; and

a control part configured to execute the maintenance recipe selected by the operation part, after end of the substrate processing when a maintenance timing of the reaction tube and/or the substrate holder arrives during execution of the substrate processing using the reaction tube.

### [Supplementary Description 2]

Preferably, there is provided the substrate processing apparatus according to the supplementary description 1, wherein a selection content can be switched in the operation part at the maintenance timing.

### [Supplementary Description 3]

Further preferably, there is provided the substrate processing apparatus according to the supplementary description 2, wherein the maintenance timing is judged by at least one setting parameter selected from a piled film thickness value, the number of times of use, and a using time of the reaction tube or the substrate holder.

### [Supplementary Description 4]

Further preferably, there is provided the substrate processing apparatus according to the supplementary description 3, wherein the setting parameter can be selected individually for each of the reaction tube and the substrate holder.

### [Supplementary Description 5]

Further preferably, there is provided the substrate processing apparatus according to any one of the supplementary descriptions 1 to 4, wherein the number of the substrate holder is larger than the number of the reaction tube.

### [Supplementary Description 6]

According to other aspect of the present invention, there is provided a substrate processing apparatus, including at least:

a substrate holder that holds a substrate;

a processing furnace including a reaction tube into which the substrate holder is loaded, and configured to apply specific processing to a substrate held by the substrate holder, with the substrate holder loaded in the reaction tube; and

a control part that executes a recipe for processing the substrate,

wherein the control part executes a recipe selected from a recipe for performing maintenance to the reaction tube, and a recipe for performing maintenance to both of the substrate holder and the reaction tube.

### [Supplementary Description 7]

Preferably, there is provided the substrate processing apparatus according to the supplementary description 6, further including:

an operation part that edits a content of the recipe,

wherein the operation part is configured to switch the recipe executed by the control part.

### [Supplementary Description 8]

Further preferably, there is provided the substrate processing apparatus according to the supplementary description 6 or the supplementary description 7, wherein the control part executes the selected recipe, when it is so judged that a maintenance timing arrives by at least one setting parameter selected from a piled film thickness value, the number of times of use, and a using time of the reaction tube or the substrate holder.

### [Supplementary Description 9]

Further preferably, there is provided the substrate processing apparatus according to the supplementary description 8, wherein the setting parameter can be set individually for each of the reaction tube and the substrate holder.

### [Supplementary Description 10]

Further preferably, there is provided the substrate processing apparatus according to any one of the sixth to ninth supplementary descriptions, wherein the number of the substrate holder is larger than the number of the reaction tube.

### [Supplementary Description 11]

According to other aspect of the present invention, there is provided a maintenance method of a substrate processing apparatus, including at least:

selecting a maintenance recipe for a reaction tube used for substrate processing, and a maintenance recipe for both of the reaction tube and a substrate holder loaded in the reaction tube; and

executing the maintenance recipe selected in the selection of the maintenance recipe, after end of the substrate processing being executed, when a maintenance timing of the reaction tube and/or the substrate holder arrives during execution of the substrate processing using the reaction tube.

### [Supplementary Description 12]

According to other aspect of the present invention, there is provided a maintenance method of a substrate processing apparatus that applies a specific processing to a substrate held by a substrate holder, in a state that the substrate holder holding a substrate is loaded in a reaction tube, the method including

executing a recipe selected from a recipe for performing maintenance to the reaction tube, and a recipe for performing maintenance to both of the substrate holder and the reaction tube.

### [Supplementary Description 13]

According to other aspect of the present invention, there is provided a substrate transfer method, including at least:

transferring a substrate to be processed, to a substrate holder;

selecting a maintenance recipe for a reaction tube used for substrate processing, and a maintenance recipe for both of the reaction tube and a substrate holder loaded in the reaction tube; and

executing the maintenance recipe selected in the selection of the maintenance recipe, after end of the substrate processing being executed, when a maintenance timing of the reaction tube and/or the substrate holder arrives during execution of the substrate processing using the reaction tube,

wherein execution of the transfer of the substrate is allowed even when the maintenance step is being executed, if the maintenance recipe for the reaction tube is selected as the maintenance recipe executed in the maintenance step.

### [Supplementary Description 14]

According to other aspect of the present invention, there is provided a substrate transfer method of a substrate processing apparatus that applies a specific processing to a substrate held by a substrate holder, in a state that the substrate holder holding a substrate is loaded in a reaction tube, the method including:

executing a recipe for processing the substrate;

transferring a substrate to be processed to a substrate holder; and

causing the control part to execute a recipe selected from a recipe for performing maintenance to the reaction tube, and a recipe for performing maintenance to both of the substrate holder and the reaction tube,

wherein execution of the transfer of the substrate is allowed even when the maintenance is being executed, if the maintenance recipe for the reaction tube is selected as the maintenance recipe executed in the maintenance step.

### [Supplementary Description 15]

According to other aspect of the present invention, there is provided a method of manufacturing a semiconductor device that applies a specific processing to a substrate held by a substrate holder in a state that the substrate holder holding a substrate is loaded in a reaction tube, the method including:

executing a recipe for processing the substrate; and

causing the control part to execute a recipe selected from a recipe for performing maintenance to the reaction tube, and a recipe for performing maintenance to both of the substrate holder and the reaction tube.

### [Supplementary Description 16]

According to other aspect of the present invention, there is provided a controller, including:

an operation part configured to select a maintenance recipe for a reaction tube used for substrate processing, and a recipe for both of the reaction tube and a substrate holder loaded in the reaction tube; and

a control part configured to execute a maintenance recipe selected by the operation part, after end of the substrate processing being executed, when a maintenance timing of the reaction tube and/or the substrate holder arrives during execution of the substrate processing using the reaction tube.

### [Supplementary Description 17]

According to other aspect of the present invention, there is provided a program executed by a substrate processing apparatus that applies a specific processing to a substrate held by the substrate holder in a state that the substrate holder holding a substrate is loaded in a reaction tube, which is the program for executing a recipe for processing the substrate, and a recipe selected from a recipe for performing maintenance to the reaction tube and a recipe for performing maintenance to both of the substrate holder and the reaction tube.

### [Supplementary Description 18]

According to other aspect of the present invention, there is provided a computer-readable recording medium recording a program for realizing:

an operation part configured to select a maintenance recipe for a reaction tube used for substrate processing, and a maintenance recipe for both of the reaction tube and a substrate holder loaded in the reaction tube; and

a control part configured to execute the maintenance recipe selected by the operation part, after end of the substrate processing being executed, when a maintenance timing of the reaction tube and/or the substrate holder arrives during execution of the substrate processing using the reaction tube.

### [Supplementary Description 19]

According to other aspect of the present invention, there is provided a computer-readable recording medium recording a program executed by a substrate processing apparatus including at least a processing furnace having a reaction tube in which a substrate holder holding a substrate is loaded, and configured to apply a specific processing to the substrate held by the substrate holder in a state that the substrate holder is loaded in the reaction tube, which is the program for executing a recipe for processing the substrate, and a recipe selected from a recipe for performing maintenance to the reaction tube, and a recipe for performing maintenance to both of the substrate holder and the reaction tube.

What is claimed is:

1. A substrate processing apparatus, comprising at least:
a substrate holder that holds a substrate;
a processing furnace including a reaction tube in which the substrate holder is loaded, and is configured to apply a specific processing to the substrate held by the substrate holder in a state that the substrate holder is loaded in the reaction tube;
an operation part configured to select a maintenance recipe for the reaction tube used for substrate processing, and a maintenance recipe for both of the reaction tube and the substrate holder loaded in the reaction tube; and
a control part configured to execute the maintenance recipe selected by the operation part, when a maintenance timing of the reaction tube and/or the substrate holder arrives.

2. A maintenance method of a substrate processing apparatus comprising:
a substrate holder that holds a substrate;
a processing furnace including a reaction tube in which the substrate holder is loaded, and is configured to apply a specific processing to the substrate held by the substrate holder in a state that the substrate holder is loaded in the reaction tube; and
a control part that executes a recipe for processing the substrate, the method comprising at least:
selecting a maintenance recipe for the reaction tube used for substrate processing, and a maintenance recipe for both of the reaction tube and the substrate holder loaded in the reaction tube; and
executing the maintenance recipe selected in the selection of the maintenance recipe, after end of the substrate processing being executed, when a maintenance timing of the reaction tube and/or the substrate holder arrives during execution of the substrate processing using the reaction tube.

3. A substrate transfer method performed in a substrate processing apparatus comprising:
a substrate holder that holds a substrate;
a processing furnace including a reaction tube in which the substrate holder is loaded, and is configured to apply a specific processing to the substrate held by the substrate holder in a state that the substrate holder is loaded in the reaction tube; and
a control part that executes a recipe for processing the substrate, the method comprising at least:
transferring a substrate to be processed to the substrate holder;
selecting a maintenance recipe for the reaction tube used for substrate processing, and a maintenance recipe for both of the reaction tube and the substrate holder loaded in the reaction tube; and
executing the maintenance recipe selected in the selection of the maintenance recipe, after end of the substrate processing being executed, when a maintenance timing of the reaction tube and/or the substrate holder arrives during execution of the substrate processing using the reaction tube,
wherein execution of the transfer of the substrate is allowed even when the execution of the maintenance recipe is being executed, if the maintenance recipe for the reaction tube is selected as the maintenance recipe executed in the maintenance step.

4. A computer-readable recording medium recording a program executed by a substrate processing apparatus, comprising:
a substrate holder that holds a substrate;
a processing furnace that applies a specific processing to the substrate held by the substrate holder in a state that the substrate holder is loaded in the reaction tube;
an operation part configured to select a maintenance recipe for the reaction tube used for substrate processing, and a maintenance recipe for both of the reaction tube and the substrate holder loaded in the reaction tube; and
a control part configured to execute the maintenance recipe selected by the operation part, after end of the substrate processing when a maintenance timing of the reaction tube and/or the substrate holder arrives during execution of the substrate processing using the reaction tube.

5. The substrate processing apparatus according to claim 1, wherein selection contents can be switched in the operation part when the maintenance timing arrives.

6. The substrate processing apparatus according to claim 5, wherein the maintenance timing is judged by at least one setting parameter selected from a piled film thickness value, the number of times of use, and a using time of the reaction tube or the substrate holder.

7. The substrate processing apparatus according to claim 6, wherein the setting parameter can be selected individually for each of the reaction tube and the substrate holder.

8. The substrate processing apparatus according to claim 1, wherein a maintenance recipe for the reaction tube used for substrate processing, and a maintenance recipe for both of the reaction tube and the substrate holder loaded in the reaction tube, is a gas cleaning recipe respectively.

9. The substrate processing apparatus according to claim 1, wherein a maintenance recipe for the reaction tube used for substrate processing is a purge cleaning recipe, and a maintenance recipe for both of the reaction tube and the substrate holder loaded in the reaction tube is a gas cleaning recipe.
